(19) United States
(12) Patent Application Publication
(10) Pub. No.: US 2018/0090198 A1
(43) Pub. Date: Mar. 29, 2018

(54) METHODS AND APPARATUS TO CONFIGURE REFERENCE VOLTAGES

(71) Applicant: Intel Corporation, Santa Clara, CA (US)

(72) Inventor: Daniel Becerra Perez, Zapopan (MX)

(21) Appl. No.: 15/274,757

(22) Filed: Sep. 23, 2016

(51) Int. Cl. G11C 11/4099; G11C 11/4096; G06F 3/06

(52) U.S. Cl. CPC G11C 11/4099; G11C 11/4096; G06F 3/067; G06F 3/0659; G06F 3/0604

(57) ABSTRACT

A disclosed example includes setting a first reference voltage value in a memory device for use during operation of the memory device in a per-device addressability (PDA) mode, the first reference voltage value for use by the memory device to determine a first logic value at a data line of the memory device during the PDA mode, the PDA mode to enable access to the memory device exclusive of other memory devices in circuit with the memory device; and setting a second reference voltage value in the memory device for use during operation of the memory device in a non-PDA mode, the non-PDA mode to enable writing data to the memory device, the second reference voltage value for use by the memory device to determine a second logic value at the data line of the memory device during a write operation.

### FIELD OF THE DISCLOSURE

The present disclosure relates generally to memory devices and, more particularly, to methods and apparatus to configure reference voltages.

### BACKGROUND

Electronic memory devices include nonvolatile memory devices and volatile memory devices. Nonvolatile memory devices persist data regardless of whether power is applied. Volatile memory devices persist data as long as power is applied. Dynamic random access memory (DRAM) is a form of volatile memory. To persist data, a DRAM device performs self-refresh cycles. During a self-refresh cycle, electrical charges on DRAM cells are refreshed to ensure that they reflect the most recent programmed data.

To write or program data into a DRAM device, a memory controller provides voltage levels representative of corresponding logic values (e.g., a binary zero or a binary one) to data lines of the DRAM device. The DRAM device interprets the voltage levels to determine the corresponding logic levels intended by the memory controller. The DRAM device then writes or programs the logic levels to corresponding memory cells at address locations specified by the memory controller.

### BRIEF DESCRIPTION OF THE DRAWINGS

FIG. 1A depicts factors that contribute to signal degradation between a memory controller transmitter and a memory device receiver.

FIG. 1B depicts example binary logic values in association with data line reference voltage (V_{REF}DQ) training increments used during a V_{REF}DQ margining process of a memory device.

FIG. 1C depicts an example eye diagram showing voltage margins defining limits of V_{REF}DQ values useable by a memory device to detect the binary logic levels of FIG. 1A via data lines of the memory device.

FIG. 1D is an example table showing the same non-optimal V_{REF}DQ value set for a number of memory devices.

FIG. 1E is an example table showing different per-device V_{REF}DQ values set for a number of memory devices.

FIG. 2 illustrates an example memory module including a number of dynamic random access memory devices configured in accordance with teachings of this disclosure to configure V_{REF}DQ values.

FIG. 3 is an example memory controller implemented in accordance with teachings of this disclosure to configure V_{REF}DQ values for use by the memory devices of FIG. 2.

FIG. 4 is the example V_{REF}DQ mode register of FIG. 2 that may be used with the example memory devices of FIGS. 2 and 3 to implement example techniques disclosed herein to configure V_{REF}DQ values for the memory devices during a V_{REF}DQ margining process.

FIG. 5A depicts an example V_{REF}DQ selection circuit that may be used to implement an example MRS qualify V_{REF}DQ multiple-set technique for setting different V_{REF}DQ values for the memory devices of FIGS. 2 and 3 during a V_{REF}DQ margining process.

FIG. 5B depicts an alternative example V_{REF}DQ selection circuit that may be used to implement an example MRS qualify V_{REF}DQ single-set technique for setting different V_{REF}DQ values for the memory devices of FIGS. 2 and 3 during a V_{REF}DQ margining process.

FIG. 6 is an example timing diagram for issuing MRS commands to memory devices of FIGS. 2, 3, 5A, and 5B.

FIG. 7 is an example V_{REF}DQ margining process timeline showing operations for performing a V_{REF}DQ margining process of the example memory devices of FIGS. 2, 3, 5A, and 5B.

FIG. 8 is a flow diagram representative of an example process that may be executed to program one or more MRS qualify V_{REF}DQ values in the memory devices of FIGS. 2, 3, and 5A using a MRS qualify V_{REF}DQ multiple-set technique.

FIG. 9 is a flow diagram representative of an example process that may be executed to program one or more MRS qualify V_{REF}DQ values in the memory devices of FIGS. 2, 3, and 5B using a MRS qualify V_{REF}DQ single-set technique.

FIG. 10 is a flow diagram representative of an example process that may be executed to implement the example memory devices of FIGS. 2, 3, 5A, and 5B in accordance with teachings of this disclosure to configure V_{REF}DQ values for use by the example memory devices to detect logic levels based on voltages applied to data lines of the memory devices.

FIG. 11 is a flow diagram representative of an example process that may be executed to implement the example memory controller of FIG. 3 in accordance with teachings of this disclosure to configure V_{REF}DQ values in the example memory devices of FIGS. 2, 3, 5A, and 5B.

FIG. 12 is an example processor platform capable of executing the example computer readable instructions represented by FIGS. 8, 9, 10 and/or 11 to implement the example memory devices of FIGS. 2, 3, 5A, and 5B, the memory module of FIGS. 2 and 3, and/or the example memory controller of FIG. 3 in accordance with teachings of this disclosure to configure V_{REF}DQ values in the example memory devices to detect logic levels based on voltages applied to data lines of the memory devices.

The figures are not to scale. Wherever possible, the same reference numbers will be used throughout the drawing(s) and accompanying written description to refer to the same or like parts.

### DETAILED DESCRIPTION

Examples disclosed herein may be used to configure reference voltages (e.g., data line reference voltages) in dynamic random access memory (DRAM) devices. DRAM is a volatile memory that stores data as long as power is applied. That is, unlike nonvolatile memory (e.g., flash memory) which persists data even when power is removed, DRAM persists data only when power is applied and loses data contents when power is removed. However, DRAM has much higher data access speeds (e.g., read/write speeds) than nonvolatile memory. Many types of electronic devices include DRAM and nonvolatile memory. For example, electronic devices use nonvolatile memory to satisfy long-term storage needs of data needing to be persisted when power is removed from the electronic devices. However, the electronic devices use DRAM to satisfy data throughput requirements to facilitate high-speed processing for data access intensive applications. In some examples, upon power up or during operation, an electronic device can copy data (e.g., frequently accessed data, most recently accessed data, and/or data that will be accessed as part of an initialized program or process) from the nonvolatile memory and store the data in the DRAM so that any subsequent accesses to that data can be performed at the DRAM at higher speeds than can be achieved using the nonvolatile memory.

To access and control DRAM, a volatile memory controller (e.g., a DRAM controller) is provided in circuit between a processor and the DRAM. In some examples, a volatile memory controller (e.g., a DRAM controller) is integrated with the processor (e.g., on a same die as the host processor or on a separate die but in the same chip package). When the processor requires data to be read from the DRAM, the processor sends a read request to the memory controller. In turn, the memory controller sends a corresponding read command to the DRAM, receives the requested data from the DRAM, and sends the received data to the processor. When the processor requires data to be written to the DRAM, the processor sends a write request to the memory controller along with the data to be written. In turn, the memory controller sends a write command and the data to the DRAM.

During a write operation, the memory controller provides voltage levels on the data lines of the DRAM corresponding to logic values (e.g., binary zeros and/or binary ones) of the data to be written. To identify the logic values to be written, the DRAM uses a data line reference voltage value (V_{REF}DQ) to compare against the voltage levels provided by the memory controller on the data lines. In DRAM devices based on prior versions of the JEDEC (Joint Electron Device Engineering Council) DDRx standards, the V_{REF}DQ was generated externally and provided to the DRAM devices via a power supply pin. However, in newer DRAM devices such as double data rate fourth generation (DDR4) (e.g., defined by the JEDEC Association in JEDEC Specification JESD79-4A), the V_{REF}DQ is generated in the DRAM device. The V_{REF}DQ level generated in the DRAM directly affects the accuracy with which the DRAM identifies the intended logic values provided by the DRAM controller at the data lines of the DRAM. For example, to detect a binary one at a data line of the DRAM, the voltage applied by the memory controller on the data line must exceed the V_{REF}DQ level generated by the DRAM, and to detect a binary zero at the data line, the voltage applied by the memory controller on the data line must be less than the V_{REF}DQ level. In such examples, if the V_{REF}DQ level is too high, the DRAM may not properly identify binary ones at the data lines because the voltage levels applied by the memory controller for intended binary ones may not exceed the V_{REF}DQ level generated by the DRAM. If the V_{REF}DQ level is too low, the DRAM may not properly identify binary zeros at the data lines because the voltage levels applied by the memory controller for the intended binary zeros may not be less than the V_{REF}DQ level generated by the DRAM.

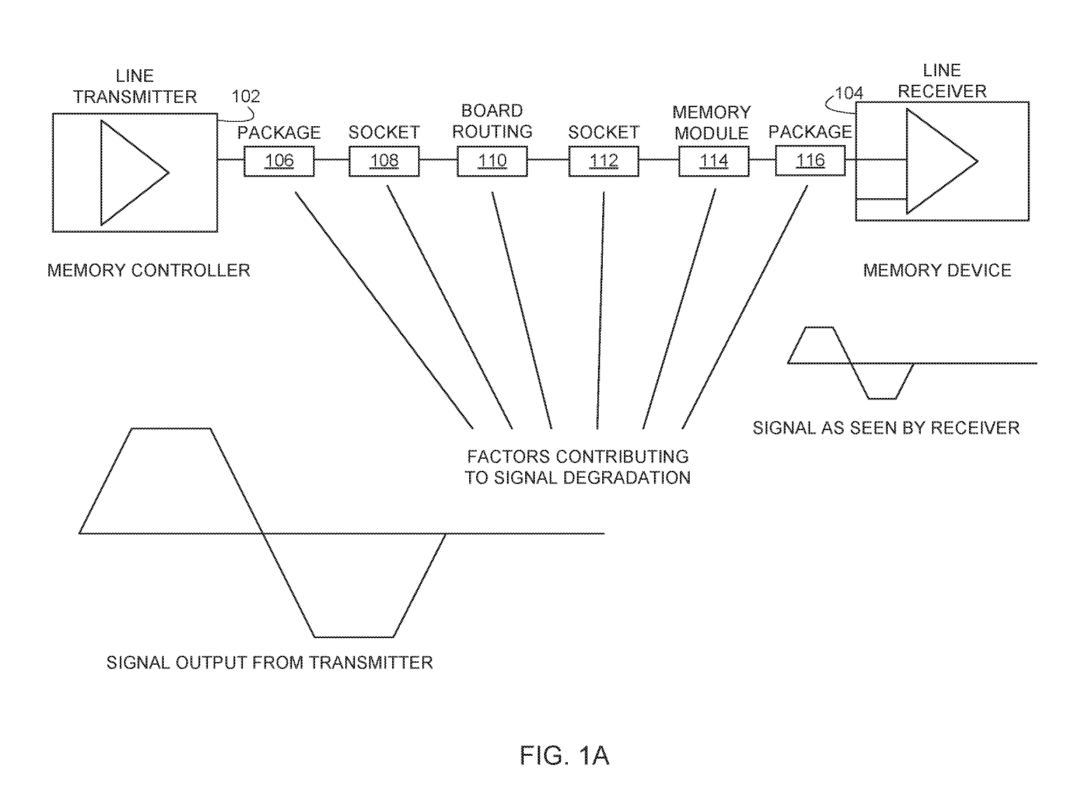

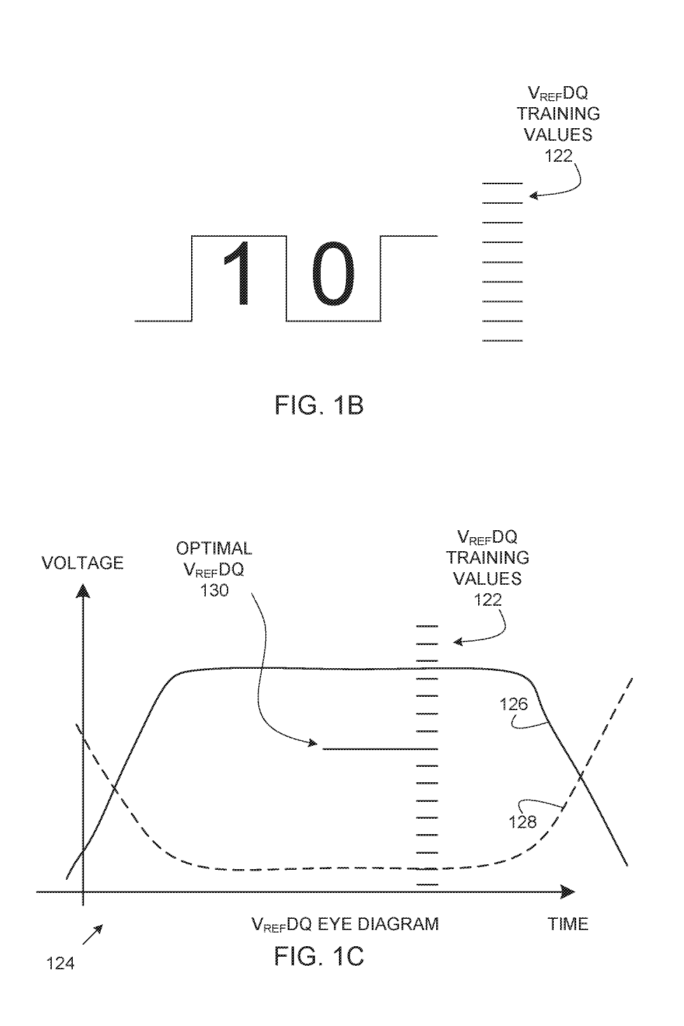

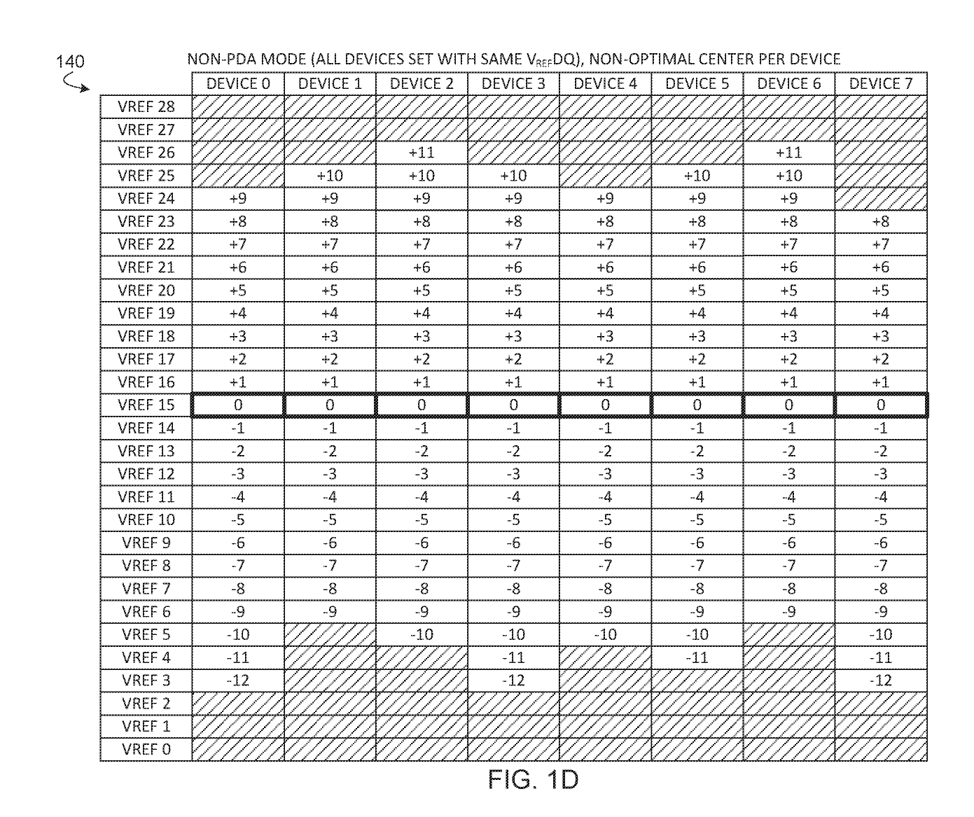

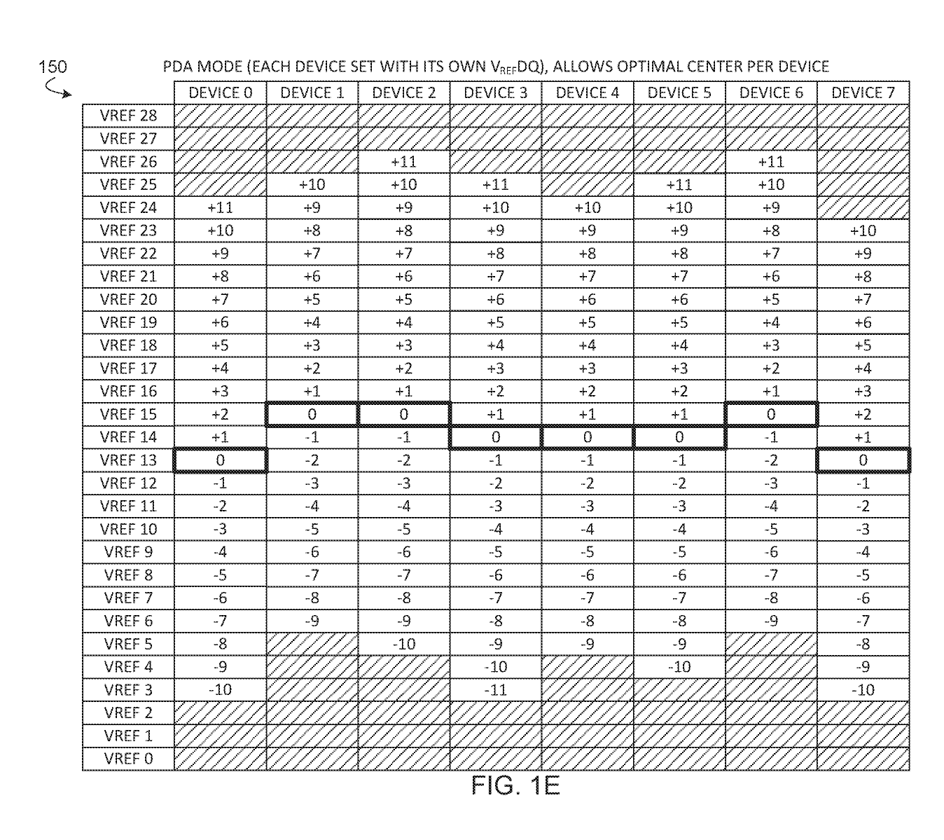

FIG. 1A depicts factors that contribute to signal degradation between a line transmitter 102 of a memory controller and a line receiver 104 of a DRAM device. In the illustrated example, a number of signal degradation factors decrease the signal integrity as seen by the line receiver 104 relative to the signal integrity as transmitted by the line transmitter 102. Due to signal integrity effects, when a signal carrying information (logic ones and logic zeros) propagates through data lines between a memory controller and a memory device, the signal is degraded as it propagates through an integrated circuit (IC) package 106 of the memory controller, through a socket 108 of the memory controller, through signal line board routing of a printed circuit board (PCB) 110, through a socket 112 of a memory module 114, through the memory module 114 (e.g., a dual inline memory module (DIMM), a single inline memory module (SIMM), etc.), and finally through the IC package 116 of the memory device. These factors may be referred to as post-fabrication factors. Other example post-fabrication factors include variations in main power supply voltage (VDD), electrical characteristics of PCBs, electrical characteristics of circuit layouts, electrical characteristics of PCB line routing, operating temperatures, electrical characteristics of silicon design, IC packaging, etc. Such factors contribute to significant signal degradation in the high and low voltage levels of the resultant signal seen by the line receiver 104 of the memory device. In some instances, such signal degradation can vary based on a common mode signal, which is affected by direct-current (DC) levels, impedance characteristics of a driver circuit (e.g., the line transmitter 102 of the memory controller) and a receiver circuit (e.g., the line receiver 104 of the memory device), channel resistance, and a receiver's termination resistance. In addition, different electrical characteristics in silicon design, IC packaging, board routing, memory modules, etc. contribute to variations in high, low and common mode levels of propagating signals between a memory controller and a memory device. To accurately detect, or recover, the logic information transmitted in such propagating signals at a DRAM device, the DRAM device is calibrated to maximize the reliability of such data detection/recover. For example, a data line reference voltage (V_{REF}DQ) of the memory device is set to a middle voltage level that is between high and low voltage levels of signals being received.

A possible solution for generating an appropriate V_{REF}DQ level in a DRAM involves calibrating and setting a V_{REF}DQ value in the DRAM during a memory die fabrication phase. Alternatively, when a memory module having a number of DRAM devices is installed in a processor system, all of the DRAM devices may be set to use the same V_{REF}DQ value. However, such solutions result in poor data detection accuracy because post-fabrication factors discussed above in connection with FIG. 1A affect what the optimal V_{REF}DQ level should be in each individual memory device when a DRAM is installed (e.g., soldered, bonded, etc.) in an electronic device for use. To overcome poor signal integrity effects arising from such post-fabrication factors, DRAM memories are designed to undergo a V_{REF}DQ margining process that allows the memory controller to test different V_{REF}DQ levels to determine an optimal V_{REF}DQ level on a per-device basis. For example, if an electrical device (e.g., a desktop computer, a mobile phone, a tablet computer, an apparatus, etc.) has multiple DRAM devices, the memory controller performs the V_{REF}DQ margining process on each DRAM device individually to configure the optimal V_{REF}DQ level for each DRAM device. The V_{REF}DQ margining process may be performed during a boot process, a hardware initialization process, a memory sub-system initialization process, and/or any time when V_{REF}DQ levels need adjusting. During the V_{REF}DQ margining process, the memory controller sets the optimal V_{REF}DQ value of each DRAM device in a mode register of that DRAM device. In this manner, each DRAM device uses its own optimal V_{REF}DQ level during operation to identify logic values provided on its data lines by the memory controller when writing data to the DRAM device. An example of V_{REF}DQ margining process is described below in connection with FIGS. 1B and 1C.

In memory circuits having multiple DRAM devices, the memory controller must be able to access each DRAM device independent of the other DRAM devices during a V_{REF}DQ margining process to determine the optimal V_{REF}DQ of each DRAM device. To facilitate such individual DRAM device access, some DRAM devices are provided with a per-DRAM addressability (PDA) mode. An example per-DRAM mode is defined by the JEDEC Association in JEDEC Specification JESD79-4A. Examples disclosed herein may be used with any JEDEC standard for DRAM and/or DDR memory devices. However, examples disclosed herein are not limited to the JEDEC Association standard for PDA mode and are not limited for use with DDR and/or DRAM devices. As such, examples disclosed herein are described in connection with a per-device addressability (PDA) mode and may be used in connection with devices other than DRAM devices. When used in connection with DRAM devices, the per-device addressability mode is a per-DRAM addressability mode.

A DRAM device includes a number of mode registers, which are configuration registers to set a number of configurations for use in operating the DRAM device. To program the mode registers, a memory controller issues mode register set (MRS) commands via, for example, memory device control lines. When control lines of a number of memory devices are in circuit with one another and with the control lines of the memory controller, an MRS command issued by the memory controller is simultaneously provided to all of the in-circuit memory devices. As part of the mode registers, the DRAM device includes a V_{REF}DQ mode register that is used to set the V_{REF}DQ value for use by that DRAM device. To determine the optimal V_{REF}DQ value during a V_{REF}DQ margining process, the memory controller must be able to configure each memory device independent of the others so that each memory device is configured with its own optimal V_{REF}DQ value. As such, the memory controller must be able to issue MRS commands to each memory device exclusive of other in-circuit memory devices. To determine the memory device for which an MRS command is intended, the memory controller uses the PDA mode to selectively issue MRS commands to individual ones of the memory devices. In the PDA mode, each memory device of a number of in-circuit memory devices is able to detect when an MRS command is intended for receipt by it based on a binary value provided to its data input/output line zero (DQ0) (e.g., data bit 0) by the memory controller. That is, in the PDA mode the data input/output line zero (DQ0) of each memory device operates as a memory device select line. For example, a binary zero on the data input/output line zero (DQ0) of a memory device during the PDA mode indicates device selection of that memory device so that the memory device processes an MRS command issued by the memory controller.

FIG. 1B depicts example binary logic values one (1) and zero (0) in association with V_{REF}DQ training values 122 used during a V_{REF}DQ margining process of a memory device. During the V_{REF}DQ margining process, a memory controller increments and decrements the V_{REF}DQ training values 122 in the memory device as described in detail below to find maximum and minimum V_{REF}DQ margins or boundaries of V_{REF}DQ values usable by the memory device to detect binary ones and binary zeros on its data lines (DQ0-DQn) during write operations. FIG. 1C shows an example eye diagram 124 that depicts an example maximum V_{REF}DQ margin 126 and an example minimum V_{REF}DQ margin 128 relative to the V_{REF}DQ training values 122. To identify the maximum V_{REF}DQ margin 126 during the V_{REF}DQ margining process, the memory controller uses MRS commands to iteratively increment the V_{REF}DQ training values 122 in the memory device. The memory device increments the V_{REF}DQ training values 122 during multiple iterations in which the memory controller also writes a binary one to the memory device and reads the written value back from the memory device. When the memory controller determines that the memory device is no longer able to read back a binary one (e.g., the memory device is no longer able to correctly detect a binary one at its data line during the write operation because the voltage level applied by the memory controller to the data line to represent a binary one does not exceed a current V_{REF}DQ training value 122 set in the memory device), the memory controller determines that it has found the maximum V_{REF}DQ margin 126 of the memory device. To identify the minimum V_{REF}DQ margin 128 during the V_{REF}DQ margining process, the memory controller uses MRS commands to iteratively decrement the V_{REF}DQ training values 122 in the memory device. The memory device decrements the V_{REF}DQ training values 122 during multiple iterations in which the memory controller also writes a binary zero to the memory device and reads the written value back from the memory device. When the memory controller determines that the memory device is no longer able to read back a binary zero (e.g., the memory device is no longer able to correctly detect a binary zero at its data line during the write operation because the voltage level applied by the memory controller to the data line to represent a binary zero is not less than a current V_{REF}DQ training value 122 set in the memory device), the memory controller determines that it has found the minimum V_{REF}DQ margin 126 of the memory device. The memory controller then uses the detected maximum V_{REF}DQ margin 126 and the minimum V_{REF}DQ margin 128 to determine an optimal V_{REF}DQ value 130 (FIG. 1C) for the memory device. In the illustrated example, the optimal V_{REF}DQ value 130 is a voltage level between the maximum V_{REF}DQ margin 126 and the minimum V_{REF}DQ margin 128 that results in producing a smallest possible bit error rate (BER) for data written to a corresponding memory device.

During initialization (e.g., at power up), the mode registers of a DRAM device are reset to default values, or invalid values. As such, the DRAM device does not have an optimal V_{REF}DQ value 130 programmed in its V_{REF}DQ mode register. FIG. 1D is an example table 140 showing the same non-optimal V_{REF}DQ value (specified using register value VREF 15) set for a number of memory devices (DEVICE 0-DEVICE 7). The non-optimal V_{REF}DQ value of FIG. 1D can be determined using a V_{REF}DQ margining process for all of the memory devices simultaneously using a non-PDA mode. Ideally, the programmed V_{REF}DQ value should be at about the center of acceptable maximum and minimum V_{REF}DQ values of each memory device. However, the non-PDA mode V_{REF}DQ margining process corresponding to the table of FIG. 1D does not result in such a per-device V_{REF}DQ optimization.

FIG. 1E is an example table 150 showing different per-device V_{REF}DQ values set for a number of memory devices (DEVICE 0-DEVICE 7). In the example table 150, each per-device V_{REF}DQ center can be obtained by detecting the maximum V_{REF}DQ margin and the minimum V_{REF}DQ margin, and calculating the center optimal V_{REF}DQ value based on the maximum and minimum V_{REF}DQ margins. Once trained, the margin is represented by offsets from the trained optimal V_{REF}DQ value. Each offset is represented by the positive and negative numbers in each cell in the example table 150. In order to preserve the correct offset, each memory device may have a different V_{REF}DQ value. For example, in the example table 150, margining one offset value away from the center in a positive direction (+1) yields a V_{REF}DQ setting of 14 for DEVICE 0, a V_{REF}DQ setting of 16 for DEVICES 1 and 2, a V_{REF}DQ setting of 15 for devices 3 to 5, etc.

The per-device V_{REF}DQ values of FIG. 1E can be determined using a V_{REF}DQ margining process that uses a PDA mode to margin each memory device separately as described above to find the optimal V_{REF}DQ value 130 for the memory device. However, iteratively cycling through different ones of the V_{REF}DQ training values 122 during the V_{REF}DQ margining process may lead to undesirable results in communicating with the memory device. For example, using the PDA mode makes it challenging to perform the V_{REF}DQ margining process because under the PDA mode each DRAM device receives a number of MRS commands from the memory controller that the DRAM device must qualify as MRS commands intended for it exclusive of other memory devices by confirming a logical value on its data input/output line zero (DQ0) (e.g., a binary zero on DQ0 confirms an MRS command from the memory controller intended for the memory device, and a binary one on DQ0 does not confirm an MRS command from the memory controller intended for the memory device). However, since the DRAM device is not yet programmed with an optimal V_{REF}DQ value 130 (FIG. 1C), the DRAM device may not correctly determine logical values on DQ0 intended by the memory controller during a margining process to qualify MRS commands issued by the memory controller.

In addition, during the V_{REF}DQ margining process, undesirable results may arise when V_{REF}DQ training values 122 are decremented too low or are incremented too high. For example, when decrementing the V_{REF}DQ training values 122 to identify the minimum V_{REF}DQ margin value 128, at some point a V_{REF}DQ training value 122 will be too low to allow the DRAM device to detect a binary zero at its data input/output line zero (DQ0) and respond to (e.g., qualify) an MRS command. That is, the V_{REF}DQ training values 122 will be decremented to a value so low that a voltage level provided by a memory controller to represent binary zero on the data input/output line zero (DQ0) of the memory device will not be lower than the currently set V_{REF}DQ training value 122. Under such circumstances, the memory device is no longer able to reliably respond to subsequent MRS commands because the memory device cannot detect the binary zero on its data input/output line zero (DQ0) used to qualify the MRS commands to continue the V_{REF}DQ margining process. Additionally, when incrementing the V_{REF}DQ training values 122 to identify the maximum V_{REF}DQ margin value 126, at some point a V_{REF}DQ training value 122 will be too high to allow the DRAM device to detect a binary one at its data input/output line zero (DQ0) and ignore an MRS command that is not intended for it. That is, the V_{REF}DQ training values 122 are incremented to a value so high that a voltage level provided by a memory controller to represent a binary one on the data input/output line zero (DQ0) of the memory device will not exceed the currently set V_{REF}DQ training value 122. Under such circumstances, the memory device is no longer able to reliably detect binary ones and, as such, will qualify and process all MRS commands issued by the memory controller even though some or all MRS commands are not intended for it (e.g., the memory controller may be performing V_{REF}DQ margining processes on other in-circuit memory devices in a selective manner using the PDA mode).

Examples disclosed herein overcome the above challenges to enable DRAM devices to correctly qualify MRS commands in a PDA mode during V_{REF}DQ margining processes. Examples disclosed herein provide two V_{REF}DQ values, one for use to qualify MRS commands, and one for use in testing different ones of the V_{REF}DQ training values 122 during memory access operations of a V_{REF}DQ margining process to find the maximum V_{REF}DQ margin 126, the minimum V_{REF}DQ margin 128, and the optimal V_{REF}DQ value 130. The V_{REF}DQ value used for qualifying MRS commands is referred to herein as an MRS qualify V_{REF}DQ value. The V_{REF}DQ value used for testing different ones of the V_{REF}DQ training values 122 is referred to herein as an operational V_{REF}DQ value.

Examples for performing a V_{REF}DQ margining process include an example MRS qualify V_{REF}DQ multiple-set technique and an example MRS qualify V_{REF}DQ single-set technique. Using the example MRS qualify V_{REF}DQ multiple-set technique, the MRS qualify V_{REF}DQ value can be set in a memory device multiple times when necessary without needing to reset/re-initialize the memory device. Using the example MRS qualify V_{REF}DQ single-set technique, the MRS qualify V_{REF}DQ value is settable one time in a memory device between memory device resets/re-initializations. As such, once an MRS qualify V_{REF}DQ value is set once in the memory device, the memory device must be reset/re-initialized should a different MRS qualify V_{REF}DQ value need to be set in the memory device (e.g., the previously set MRS qualify V_{REF}DQ value is not useful by the memory device to properly qualify MRS commands). In both the MRS qualify V_{REF}DQ multiple-set technique and the MRS qualify V_{REF}DQ single-set technique, when an acceptable MRS qualify V_{REF}DQ value is set in the memory device, the memory device can use the acceptable MRS qualify V_{REF}DQ value to properly qualify MRS commands in the PDA mode during a V_{REF}DQ margining process to increment/decrement the operational V_{REF}DQ value to test different ones of the V_{REF}DQ training values 122 for determining V_{REF}DQ margins (e.g., the maximum V_{REF}DQ margin 126 and the minimum V_{REF}DQ margin 128 of FIG. 1C).

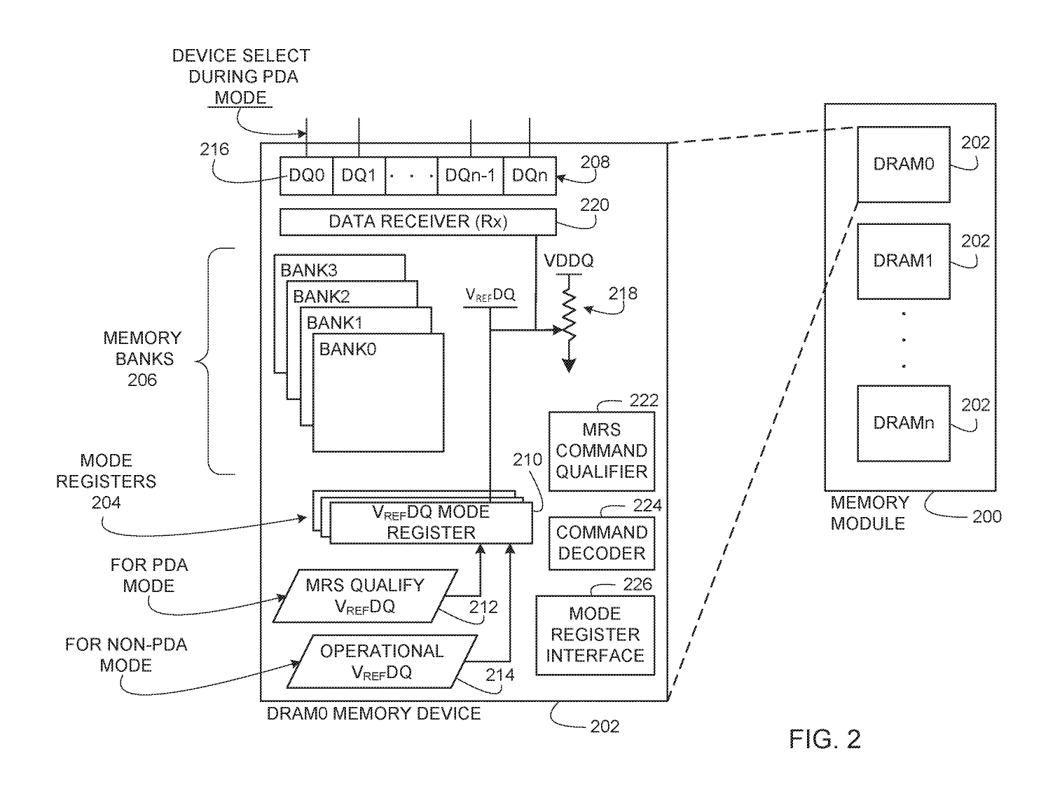

FIG. 2 illustrates an example memory module 200 including a number of DRAM devices 202 configured in accordance with teachings of this disclosure to configure V_{REF}DQ values for each DRAM device 202. In examples disclosed herein a memory device (e.g., a memory device 202 of FIG. 2) is an individual memory die or memory chip, and a memory module (e.g., the memory module 200 of FIG. 2) includes multiple memory devices in-circuit with one another to be installed in-circuit with a memory controller (e.g., an example memory controller 200 of FIG. 2). Examples of memory modules include a dual in-line memory module (DIMM) and a single in-line memory module (SIMM) that are intended to be removably installed on a main PCB to place the memory devices of the memory module in-circuit with a memory controller. In some examples, a group of in-circuit memory devices 202 may be located (e.g., bonded, soldered, mounted, etc.) directly on a main PCB in-circuit with a memory controller instead of on a separate memory module 200. Thus, although the memory module 200 is shown in FIG. 2, examples disclosed herein may be used in connection with DRAM devices located directly on main PCBs.

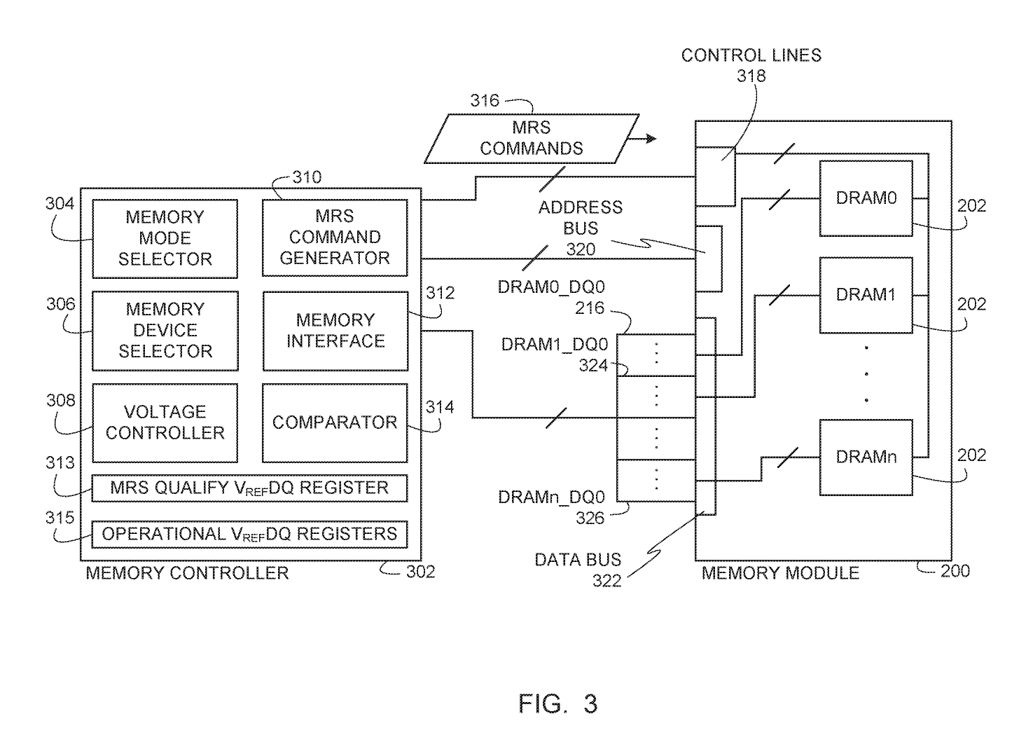

In the illustrated example, the memory module 200 includes eight DRAM devices 202, of which three are shown as DRAM0, DRAM1, and DRAMn. A more detailed view of the DRAM0 memory device 202 is shown in the illustrated example. The memory device 202 of the illustrated example includes example mode registers 204, example memory banks 206, and an example data bus 208. The example mode registers 204 are used to store settings for different features of the memory device 202 including, for example, V_{REF}DQ values, latency, burst sequence, burst length, etc. The mode registers 204 of the illustrated example remain programmed until they are reprogrammed or power is removed from the memory device 202. An example V_{REF}DQ mode register 210 is shown as part of the mode registers 204. The example V_{REF}DQ mode register 210 stores V_{REF}DQ values for use by the memory device 202. In the illustrated example, the V_{REF}DQ mode register 210 stores an example MRS qualify V_{REF}DQ value 212 and an example operational V_{REF}DQ value 214 received from a memory controller (e.g., the example memory controller 302 of FIG. 3). In the illustrated example, the memory device 202 uses the MRS qualify V_{REF}DQ value 212 during a per-device addressability (PDA) mode to qualify MRS commands (e.g., to confirm when MRS commands are received from a memory controller), and uses the operational V_{REF}DQ value 214 during a non-PDA mode in which data reads and/or writes can be performed on the memory device 202.

In examples disclosed herein, the operational V_{REF}DQ value 214 is used by the memory device 202 to determine binary values at the data lines of the data bus 208 based on comparing voltage levels at those data lines to the operational V_{REF}DQ value 214. Although examples disclosed herein are described in connection with determining the operational V_{REF}DQ value 214 for use with the data lines of the data bus 208, examples disclosed herein can be similarly used to determine operational V_{REF} values for use with control lines (e.g., control lines 318 of FIG. 3) and/or address lines (e.g., an address bus 320 of FIG. 3) of the memory device 202. In this manner, operational V_{REF} control line values determined using techniques disclosed herein can be used by the memory device 202 to detect commands from a memory controller based on comparisons between voltage levels at the control lines and an operational V_{REF} control line value. Similarly, operational V_{REF} address line values determined using techniques disclosed herein can be used by the memory device 202 to detect addresses from the memory controller based on comparisons between voltage levels at the address bus and an operational V_{REF} address line value.

The memory banks 206 include corresponding arrays of memory cells that can be addressed for data access by a memory controller. The data bus 208 is in circuit with data lines of the memory module 200 to receive data to be written from a memory controller and/or to send data read from the memory device 202 to the memory controller. In the illustrated example, the data bus 208 is shown as including a plurality of data lines (DQ0, DQ1, DQn−1, DQn). In the illustrated example, a data input/output line zero (DQ0) 216 is used as a memory device select line during a PDA mode. For example, when a memory controller performs a V_{REF}DQ margining process on the DRAM0 memory device 202 in the PDA mode, the memory controller provides a binary value of zero on the data input/output line zero (DQ0) 216 of the DRAM0 memory device 202 to select the DRAM0 memory device 202. In this manner, when the DRAM0 memory device 202 detects the binary zero at its data input/output line zero (DQ0) 216, the DRAM0 memory device 202 qualifies an MRS command from the memory controller as intended to be received and processed by the DRAM0 memory device 202.

To determine binary values corresponding to voltage values on the data bus 208, the memory device 202 is provided with an example data receiver (Rx) 220. The example data receiver 220 compares voltage levels on the data lines of the data bus 208 to the operational V_{REF}DQ value 214 during a non-PDA mode to determine binary values provided by a memory controller. During a PDA mode, the example data receiver 220 compares a voltage level on the data input/output line zero (DQ0) 216 to the MRS qualify V_{REF}DQ value 212 to determine a binary value on the data input/output line zero (DQ0) 216. The memory device 202 is also provided with a resistor ladder 218 to generate V_{REF}DQ values (e.g., the MRS qualify V_{REF}DQ value 212 and the operational V_{REF}DQ value 214) for use by the data receiver 220 to determine logic levels based on voltages applied to the data bus 208.

To qualify MRS commands from a memory controller based on a binary value applied to the data input/output line zero (DQ0) 216, the memory device 202 is provided with an example MRS command qualifier 222. For example, the MRS command qualifier 222 qualifies an MRS command from the memory controller based on the binary value of the data input/output line zero (DQ0) 216. In the illustrated example, if the binary value is zero, the MRS command qualifier 222 determines that the memory controller has selected the memory device 202 and, thus, the MRS command qualifier 222 qualifies an MRS command from the memory controller.

By using the MRS qualify V_{REF}DQ value 212 and the operational V_{REF}DQ value 214 in accordance with the teachings of this disclosure, the MRS qualify V_{REF}DQ value 212 can be set in the memory device 202 for use by the memory device 202 when it is operating in the PDA mode during a V_{REF}DQ margining process to qualify MRS commands from the memory controller independent of V_{REF}DQ training values set for the operational V_{REF}DQ value 214 during a V_{REF}DQ margining process. In this manner, during the V_{REF}DQ margining process, the memory controller can set the operational V_{REF}DQ value 214 to different incremented/decremented V_{REF}DQ training values (e.g., the V_{REF}DQ training values 122 of FIGS. 1B and 1C) for use during operation of the memory device 202 in a data access operating mode to identify maximum and minimum V_{REF}DQ margins (e.g., the maximum V_{REF}DQ margin 126 and the minimum V_{REF}DQ margin 128 of FIG. 1C) while using the MRS qualify V_{REF}DQ value 212 to qualify MRS commands. That is, in the illustrated example, the MRS qualify V_{REF}DQ value 212 is set in the memory device 202 before entering a PDA mode used during the V_{REF}DQ margining process. Because MRS commands are sent by the memory controller at a much slower speed than data during read/write operations, the MRS qualify V_{REF}DQ value 212 is not as critical as the operational V_{REF}DQ value 214. That is, the operational V_{REF}DQ value 214 requires better resolution (e.g., more granularity) to enable accurately finding passing/failing V_{REF}DQ values when testing for the maximum V_{REF}DQ margin 126 or the minimum V_{REF}DQ margin 128. The MRS Qualify V_{REF}DQ value 212 can have the same or lower resolution, because the MRS Qualify V_{REF}DQ value 212 is not used to find the margins 126, 128, but rather the MRS Qualify V_{REF}DQ value 212 is positioned in a passing region to correctly qualify an MRS command. As such, the MRS qualify V_{REF}DQ value 212 that is to be set in the memory device 202 can be selected and programmed in a memory controller in advance (e.g., during a time of manufacturing, during a memory initialization phase of a boot process, etc.). In this manner, the memory controller can program the MRS qualify V_{REF}DQ value 212 in all of the memory devices 202 without needing to optimize the MRS qualify V_{REF}DQ value 212 for any particular memory device 202. The memory device 202 can then use the MRS qualify V_{REF}DQ value 212 in the PDA mode to qualify subsequent MRS commands from the memory controller during the V_{REF}DQ margining process. Because the same MRS qualify V_{REF}DQ value 212 is used during the V_{REF}DQ margining process, the memory device 202 can consistently qualify MRS commands from the memory controller based on the same MRS qualify V_{REF}DQ value 212 during the V_{REF}DQ margining process even though the operational V_{REF}DQ value 214 is being incremented and/or decremented with different V_{REF}DQ training values 122 (FIGS. 1B and 1C).

To determine when to use the MRS qualify V_{REF}DQ value 212 and when to use the operational V_{REF}DQ value 214, the memory device 202 is provided with an example command decoder 224. The command decoder 224 of the illustrated example is configured to detect and decode MRS commands from a memory controller. In this manner, when the example command decoder 224 detects an MRS command while the memory device 202 is in PDA mode, the command decoder 224 causes the data receiver 220 to use the MRS qualify V_{REF}DQ value 212 to detect the binary value at the data input/output line zero (DQ0) 216 for use by the MRS command qualifier 222 to qualify the MRS command. In some examples, alternative configurations may involve the use of a different data input/output line (DQn) other than data input/output line zero (DQ0) and/or multiple data input/output lines for qualifying MRS commands. When the example command decoder 224 does not detect an MRS command in PDA mode from the memory controller, the command decoder 224 causes the data receiver 220 to use the operational V_{REF}DQ value 214 to determine binary values on the data bus 208 during write operations.

To program or set values in the mode registers 204, the memory device 202 is provided with an example mode register interface 226. For example, the mode register interface 226 may set a PDA mode enable bit in the mode registers 204, may set MRS qualify V_{REF}DQ values 212 in the V_{REF}DQ mode register 210, may set operational V_{REF}DQ values 214 in the V_{REF}DQ mode register 210, and/or may set any other values in the mode registers 204.

FIG. 3 is an example memory controller 302 implemented in accordance with teachings of this disclosure to configure V_{REF}DQ voltages for use by the memory devices 202 of FIG. 2. The example memory controller 302 includes an example memory mode selector 304, an example memory device selector 306, an example voltage controller 308, an example MRS command generator 310, an example memory interface 312, an example comparator 314, an example MRS qualify V_{REF}DQ register 313, and an example operational V_{REF}DQ register 315. The memory controller 302 is provided with the example memory mode selector 304 to select between a PDA mode and a non-PDA mode for the example memory devices 202. The memory controller 302 is provided with the example memory device selector 306 to select ones of the DRAM0-DRAMn memory devices 202 exclusive of others of the DRAM0-DRAMn memory devices 202 during a PDA mode. The memory controller 302 is provided with the example voltage controller 308 to select voltage levels for the MRS qualify V_{REF}DQ value 212 and the operational V_{REF}DQ value 214.

The memory controller 302 is provided with the example MRS command generator 310 to generate MRS commands for use in configuring the DRAM0-DRAMn memory devices 202. For example, the MRS command generator 310 may generate an MRS command to place the DRAM0-DRAMn memory devices 202 in PDA mode when the PDA mode is selected by the memory mode selector 304. In the illustrated example, the MRS command generator 310 places the DRAM0-DRAMn memory devices 202 in PDA mode by generating an MRS command that sets a PDA mode enable bit in one of the mode registers 204 (FIG. 2) of the DRAM0-DRAMn memory devices 202. For example, JEDEC standard JESD79-4A defines the PDA mode enable bit as being located in a mode register 3 (MR3) of the mode registers 204 (FIG. 2). In other examples, the PDA mode enable bit may be located in any other register. To enable the PDA mode, the memory controller 302 sends a PDA-enable MRS command to all of the DRAM0-DRAMn memory devices 202 to place all of the memory devices 202 in the PDA mode at the same time. In this manner, the memory controller 302 can selectively configure each of the DRAM0-DRAMn and memory devices 202 independent of others of the DRAM0-DRAMn memory devices 202 by sending a binary value of zero to a data input/output line zero (DQ0) of a memory device 202 that is intended to process a subsequent MRS command.

The memory controller 302 is provided with the example memory interface 312 to send control signals (e.g., MRS commands), addresses, and data to the memory devices 202 of the memory module 200. For example, the memory interface 312 sends MRS commands 316 generated by the MRS command generator 310 to control lines 318 of the memory devices 202. Although not shown, in some examples the memory interface 312 may send the MRS commands 316 using the control lines 318 and an address bus 320 of the DRAM0-DRAMn memory devices 202. The example memory interface 312 also sends V_{REF}DQ training values (e.g., the V_{REF}DQ training values 122) to a data bus 322 of the memory module 200 using corresponding MRS commands 316. In the illustrated example, the data bus 322 of the memory module 200 is formed by concatenating the data buses (e.g., the data bus 208) of each of the DRAM0-DRAMn memory devices 202. As such, the data bus 322 of the memory module 200 includes a number of data input/output lines zero (DQ0) corresponding to different ones of the memory devices 202 as shown in FIG. 3. For example, the data input/output line zero (DQ0) of the DRAM0 memory device 202 is shown in FIG. 3 as DRAM0_DQ0 216, the data input/output line zero (DQ0) of the DRAM1 memory device 202 is shown in FIG. 3 as DRAM1_DQ0 324, and the data input/output line zero (DQ0) of the DRAMn memory device 202 is shown in FIG. 3 as DRAMn_DQ0 326. In the illustrated example, when the DRAM0-DRAMn memory devices 202 are in the PDA mode, the memory interface 312 applies a binary value of zero to one of the data input/output lines zero 216, 324, 326 of a corresponding one of the DRAM0-DRAMn memory devices 202 that is a target for an MRS command 316. In this manner, the memory controller 302 can selectively configure each of the DRAM0-DRAMn memory devices 202 exclusive of others of the DRAM0-DRAMn memory devices 202 using the MRS commands 316 in the PDA mode.

The memory controller 302 is provided with the example comparator 314 to compare read back binary values to previously written binary values during a V_{REF}DQ margining process to determine whether a maximum V_{REF}DQ margin 126 or a minimum V_{REF}DQ margin 128 has been reached. For example, during a V_{REF}DQ margining process, the memory controller 302 writes a binary test value of one to the memory device 202 for use in finding the maximum V_{REF}DQ margin 126, and writes a binary test value of zero to the memory device 202 for use in finding the minimum V_{REF}DQ margin 128. When the memory controller 302 reads back the previously written binary test value, the example comparator 314 compares the read back binary test value to the previously written binary test value to determine whether the values match. If the comparator 314 determines that the values match, a corresponding V_{REF}DQ margin 126, 128 has not been reached because the writing of the binary test value to the memory device 202 did not fail (e.g., did not produce an error).

The example memory controller 302 is provided with the MRS qualify V_{REF}DQ register 313 to store the MRS qualify V_{REF}DQ value 212 for programming into the memory devices 202. For example, a programmer/software developer can receive from a memory device manufacturer of the memory devices 202 a default value for the MRS qualify V_{REF}DQ value 212 that is known to be in an acceptable V_{REF}DQ range for use by the memory devices 202 to qualify MRS commands 316. In some examples, the memory device manufacturer determines the default value for the MRS qualify V_{REF}DQ value 212 based on circuit simulations, laboratory testing, and/or empirical analysis of a number of memory devices. The programmer/software developer then programs the default value for the MRS qualify V_{REF}DQ value 212 in a basic input/output system (BIOS) firmware region of an electronic device in which the memory devices 202 and the memory controller 302 are located. The default MRS qualify V_{REF}DQ value 212 can be provided in the BIOS firmware at a time of manufacture of the electronic device in which the memory devices 202 and the memory controller 302 are located and/or during a firmware update after the manufacturing process. During a system initialization (e.g., a boot process), the BIOS firmware provides the MRS qualify V_{REF}DQ value 212 to the memory controller 302, and the memory controller 302 stores the MRS qualify V_{REF}DQ value 212 in the MRS qualify V_{REF}DQ register 313. In this manner, the memory controller 302 can program the MRS qualify V_{REF}DQ value 212 in the memory devices 202 for use by the memory devices 202 to qualify MRS commands 316. In some examples, if the default value for the MRS qualify V_{REF}DQ value 212 does not provide acceptable results for memory devices 202 to successfully qualify MRS commands 316, the memory device 302 can increment/decrement the MRS qualify V_{REF}DQ value 212 in the MRS qualify V_{REF}DQ register 313 one or more times, and program the one or more incremented/decremented MRS qualify V_{REF}DQ value 212 in the memory devices 202 until an acceptable MRS qualify V_{REF}DQ value 212 is found. For example, the memory controller 302 can determine that it has found an acceptable MRS qualify V_{REF}DQ value 212 when all of the memory devices 202 respond as expected to MRS commands 316. In the illustrated example, one MRS qualify V_{REF}DQ register 313 is shown for use in programming all of the memory devices 202 with the same MRS qualify V_{REF}DQ value 212. However, in other examples, more than one MRS qualify V_{REF}DQ register 313 can be provided so that different ones of the memory devices 202 can be programmed with different MRS qualify V_{REF}DQ values 212.

The example memory controller 302 is provided with the operational V_{REF}DQ register 315 to store the operational V_{REF}DQ value 214 for programming into the memory devices 202. For example, during a V_{REF}DQ margining process, the memory controller 302 can store different ones of the V_{REF}DQ training values 122 in the operational V_{REF}DQ registers 315 for programming in the memory devices 202 to find optimal operational V_{REF}DQ values 214 (e.g., the optimal V_{REF}DQ value 130). When the memory controller 302 determines the optimal operational V_{REF}DQ values 214, the optimal operational V_{REF}DQ values 214 can be stored in the operational V_{REF}DQ registers 315 and programmed by the memory controller 302 in corresponding ones of the memory devices 202.

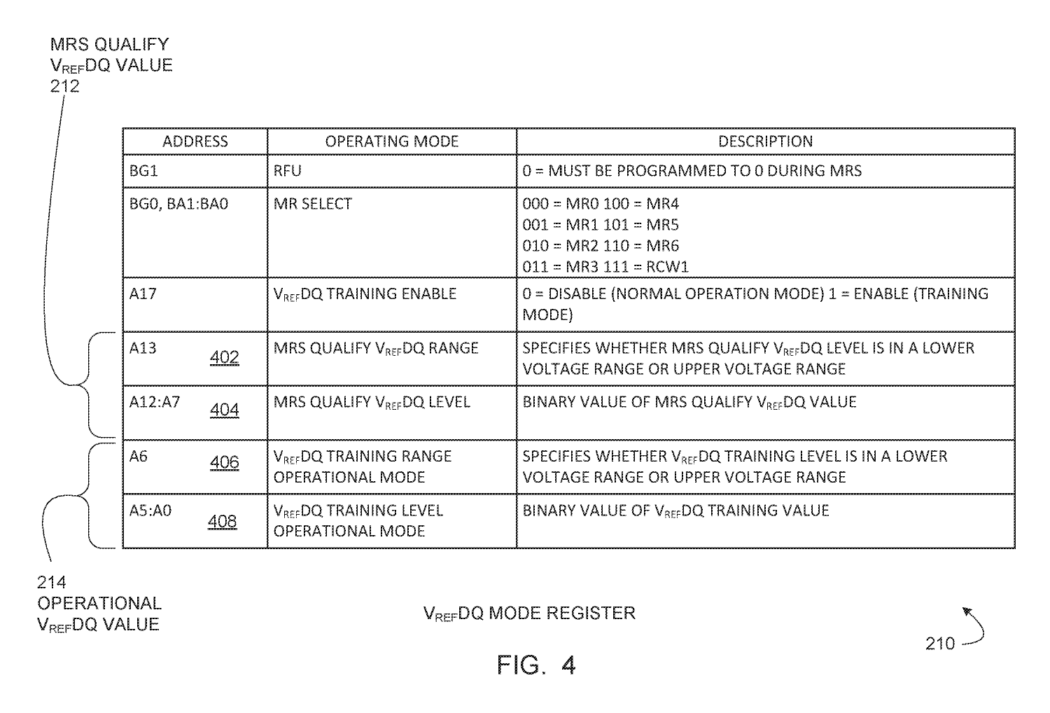

FIG. 4 is an example of the V_{REF}DQ mode register 210 (FIG. 2) of the example memory devices 202 (FIGS. 2 and 3) to perform V_{REF}DQ margining processes in accordance with examples disclosed herein. For example, the V_{REF}DQ mode register 210 may be used to implement V_{REF}DQ margining processes using an example MRS qualify V_{REF}DQ multiple-set technique and/or an example MRS qualify V_{REF}DQ single-set technique. In the example MRS qualify V_{REF}DQ multiple-set technique, the MRS qualify V_{REF}DQ value 212 may be set multiple times in a memory device 202 during a V_{REF}DQ margining process without needing to reset/re-initialize the memory device 202. In the example MRS qualify V_{REF}DQ single-set technique, the MRS qualify V_{REF}DQ value 212 may be set only once in a memory device 202 between resets/re-initializations of the memory device 202. The example V_{REF}DQ mode register 210 enables programming the MRS qualify V_{REF}DQ value 212 separately from the operational V_{REF}DQ value 214 so that different V_{REF}DQ values can be programmed for the operational V_{REF}DQ value 214 during a V_{REF}DQ margining process without affecting use of the same MRS qualify V_{REF}DQ value 212 to qualify MRS commands in a PDA mode used to perform the V_{REF}DQ margining process. That is, because the MRS qualify V_{REF}DQ value 212 can be stored separately from the operational V_{REF}DQ value 214 during the V_{REF}DQ margining process, the memory devices 202 can consistently qualify MRS commands 316 from the memory controller 302 based on the MRS qualify V_{REF}DQ value 212 even though the operational V_{REF}DQ value 214 is being incremented and/or decremented with different ones of the V_{REF}DQ training values 122.

To enable programming the MRS qualify V_{REF}DQ value 212 separately from the operational V_{REF}DQ value 214, the example V_{REF}DQ mode register 210 includes an example MRS qualify V_{REF}DQ range field 402, an example MRS qualify V_{REF}DQ level field 404, an example V_{REF}DQ training range operational mode field 406, and an example V_{REF}DQ training level operational mode field 408. In the illustrated example, the MRS qualify V_{REF}DQ value 212 is programmed in the MRS qualify V_{REF}DQ range field 402 and the MRS qualify V_{REF}DQ level field 404. Also in the illustrated example, the operational V_{REF}DQ value 214 is programmed in the V_{REF}DQ training range operational mode field 406 and the V_{REF}DQ training level operational mode field 408. In this manner, when the operational V_{REF}DQ value 214 is incremented/decremented based on different V_{REF}DQ training values 122 (FIGS. 1B and 1C) during a V_{REF}DQ margining process, storing different values for the operational V_{REF}DQ value 214 does not overwrite the MRS qualify V_{REF}DQ value 212 because the MRS qualify V_{REF}DQ value 212 and the operational V_{REF}DQ value 214 are programmed in separate fields.

In the illustrated example, the MRS qualify V_{REF}DQ range field 402 is a one-bit field, and the MRS qualify V_{REF}DQ level field 404 is a 6-bit field. However, any other number of bits may be used for each field and/or any number of fields may be used. The example MRS qualify V_{REF}DQ range field 402 is used to specify a lower voltage range (e.g., 0%-50% of a main voltage supply VDDQ) or an upper voltage range (e.g., 51%-100% of a main power supply VDDQ) in which the binary values stored in the MRS qualify V_{REF}DQ level field 404 specifies the MRS qualify V_{REF}DQ value 212. For example, the MRS qualify V_{REF}DQ range field 402 specifies whether binary value in the MRS qualify V_{REF}DQ level field 404 specifies a MRS qualify V_{REF}DQ value 212 in a lower voltage range (e.g., a binary zero set in the MRS qualify V_{REF}DQ range field 402) or in an upper voltage range (e.g., a binary one set in the MRS qualify V_{REF}DQ range field 402).

In the illustrated example, the V_{REF}DQ training range operational mode field 406 is a one-bit field, and the V_{REF}DQ training level operational mode field 408 is a 6-bit field. However, any other number of bits may be used for each field and/or any number of fields may be used. The example V_{REF}DQ training range operational mode field 406 is used to specify a lower voltage range (e.g., 0%-50% of a main voltage supply VDDQ) or an upper voltage range (e.g., 51%-100% of a main power supply VDDQ) in which the binary value stored in the V_{REF}DQ training level operational mode field 408 specifies the operational V_{REF}DQ value 214. For example, the V_{REF}DQ training range operational mode field 406 specifies whether a binary value in the V_{REF}DQ training level operational mode field 408 specifies an operational V_{REF}DQ value 214 in a lower voltage range (e.g., a binary zero set in the V_{REF}DQ training range operational mode field 406) or in an upper voltage range (e.g., a binary one set in the V_{REF}DQ training range operational mode field 406).

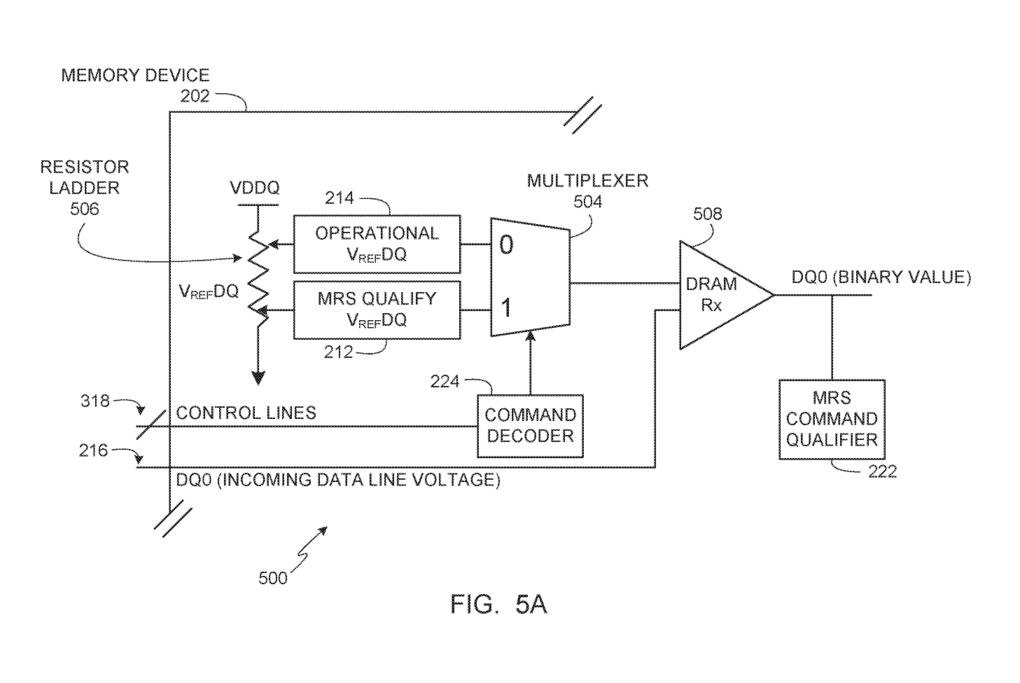

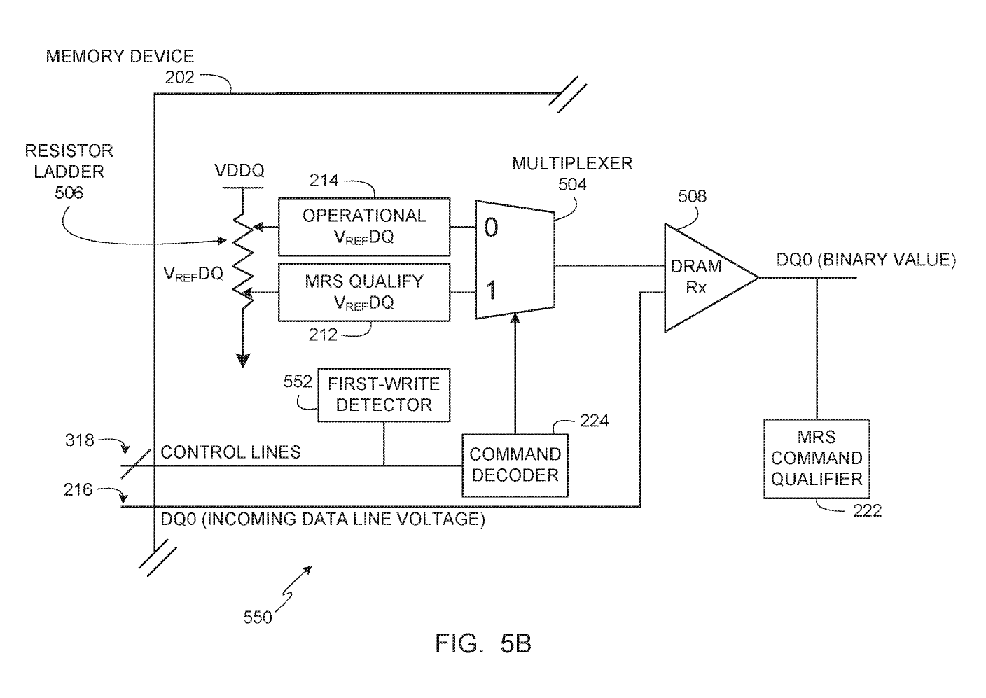

In the example MRS qualify V_{REF}DQ multiple-set technique, all of the MRS qualify V_{REF}DQ range field 402, the MRS qualify V_{REF}DQ level field 404, the V_{REF}DQ training range operational mode field 406, and the V_{REF}DQ training level operational mode field 408 are exposed external to the memory device 202 for access by the memory controller 302. In the example MRS qualify V_{REF}DQ multiple-set technique, the memory controller 302 sets the MRS qualify V_{REF}DQ value 212 in the MRS qualify V_{REF}DQ range field 402 and the MRS qualify V_{REF}DQ level field 404 of all of the memory devices 202 during a non-PDA mode (e.g., before entering into a PDA mode) by using an MRS command that addresses the MRS qualify V_{REF}DQ range field 402 and the MRS qualify V_{REF}DQ level field 404 as described below in connection with FIG. 5A.

In the example MRS qualify V_{REF}DQ single-set technique, the V_{REF}DQ training range operational mode field 406 and the V_{REF}DQ training level operational mode field 408 are exposed external to the memory device 202 for access by the memory controller 302. However, the MRS qualify V_{REF}DQ range field 402 and the MRS qualify V_{REF}DQ level field 404 are not exposed external to the memory device 202 for access by the memory controller 302. The MRS qualify V_{REF}DQ single-set technique uses a first-write detection technique to set the MRS qualify V_{REF}DQ value 212 in the MRS qualify V_{REF}DQ range field 402 and the MRS qualify V_{REF}DQ level field 404 as described below in connection with FIG. 5B.

After setting the MRS qualify V_{REF}DQ value 212 in the MRS qualify V_{REF}DQ range field 402 and the MRS qualify V_{REF}DQ level field 404, each memory device 202 can use the MRS qualify V_{REF}DQ value 212 during the PDA mode to qualify subsequent MRS commands 316 intended to be received by it for setting the operational V_{REF}DQ value 214 with a particular V_{REF}DQ training value 122 (FIGS. 1B and 1C) for testing to find a V_{REF}DQ margin (e.g., a maximum V_{REF}DQ margin 126 or a minimum V_{REF}DQ margin 128 of FIG. 1C) for that memory device 202. That is, each memory device 202 may receive a different V_{REF}DQ training value 122 because the maximum and minimum V_{REF}DQ margins may be different for each memory device 202. In the illustrated example, the memory controller 302 sets the V_{REF}DQ training values 122 in the V_{REF}DQ training range operational mode field 406 and the V_{REF}DQ training level operational mode field 408.

During subsequent iterations of a V_{REF}DQ margining process, any operational V_{REF}DQ value 214 that was set in the V_{REF}DQ training range operational mode field 406 and the V_{REF}DQ training level operational mode field 408 during a previous iteration is replaced or overwritten by a new operational V_{REF}DQ value 214 to test for a V_{REF}DQ margin based on that new operational V_{REF}DQ value 214. In this manner, the process of testing different V_{REF}DQ training values 122 for use as the operational V_{REF}DQ value 214 can be repeated by re-programming different values in the V_{REF}DQ training range operational mode field 406 and the V_{REF}DQ training level operational mode field 408 (overwriting the previously tested operational V_{REF}DQ value 214) so that new operational V_{REF}DQ values 214 (e.g., incremented/decremented V_{REF}DQ training values 122) can be tested.

FIG. 5A depicts an example V_{REF}DQ selection circuit 500 that may be used to implement an example MRS qualify V_{REF}DQ multiple-set technique during a V_{REF}DQ margining process. In the example MRS qualify V_{REF}DQ multiple-set technique, exposing the example MRS qualify V_{REF}DQ range field 402 and the example MRS qualify V_{REF}DQ level field 404 for access by the memory controller 302 enables the memory controller 302 to set the MRS qualify V_{REF}DQ value 212 in all of the DRAM0-DRAMn memory devices 202 each time before entering a PDA mode without needing to reset/re-initialize the memory devices 202. For example, the memory device 202 receives an MRS command 316 that includes the MRS qualify V_{REF}DQ value 212 and addresses the example MRS qualify V_{REF}DQ range field 402 and the example MRS qualify V_{REF}DQ level field 404. In this manner, the memory device 202 programs the MRS qualify V_{REF}DQ value 212 received from the memory controller 302 in the example MRS qualify V_{REF}DQ range field 402 and the example MRS qualify V_{REF}DQ level field 404 based on the memory controller 302 directly accessing those fields. As such, if the MRS qualify V_{REF}DQ value 212 is not yet identified to be in a passing window of acceptable V_{REF}DQ values, the MRS qualify V_{REF}DQ multiple-set technique enables varying the MRS qualify V_{REF}DQ value 212 multiple times to identify a useful value without needing to perform resets/re-initializations of the memory devices 202 that could lead to longer system initialization/boot times.

When an acceptable MRS qualify V_{REF}DQ value 212 is found, the MRS qualify V_{REF}DQ value 212 programmed into the example MRS qualify V_{REF}DQ range field 402 and the example MRS qualify V_{REF}DQ level field 404 no longer needs to be changed. In some examples, a default MRS qualify V_{REF}DQ value 212 in the MRS qualify V_{REF}DQ register 313 of the memory controller 302 is a useful value for all of the memory devices 202. In such examples, the memory controller 302 can program the MRS qualify V_{REF}DQ value 212 once into the example MRS qualify V_{REF}DQ range field 402 and the example MRS qualify V_{REF}DQ level field 404 without needing to cycle through multiple values to find a useful MRS qualify V_{REF}DQ value 212. In the illustrated example, after an acceptable MRS qualify V_{REF}DQ value 212 is identified, any time a subsequent system reset clears the example MRS qualify V_{REF}DQ range field 402 and the example MRS qualify V_{REF}DQ level field 404, the memory controller 302 can re-program the previously identified acceptable MRS qualify V_{REF}DQ value 212 from the MRS qualify V_{REF}DQ register 313 to the memory devices 202.

The example V_{REF}DQ selection circuit 500 of FIG. 5A may be used to set a same MRS qualify V_{REF}DQ value 212 in the V_{REF}DQ mode register 210 of all of the memory devices 202 of a memory module 200 (FIG. 2) during a non-PDA mode so that the memory devices 202 can use the MRS qualify V_{REF}DQ value 212 to qualify subsequent MRS commands 316 targeted by the memory controller 302 to different ones of the memory devices 202. In this manner, the memory controller 302 can test different V_{REF}DQ training values 122 in each memory device 202 to find an optimal operational V_{REF}DQ value 214 for that memory device 202.

In the illustrated example of FIG. 5A, the V_{REF}DQ selection circuit 500 switches between the MRS qualify V_{REF}DQ value 212 and the operational V_{REF}DQ value 214 as the V_{REF}DQ value for use by the memory device 202 based on MRS commands 316 provided by the memory controller 302 (FIG. 3). The example V_{REF}DQ selection circuit 500 is provided with the example command decoder 224 of FIG. 2, an example multiplexer 504, an example resistor ladder 506 and an example data receiver 508. In the illustrated example, when the command decoder 224 detects an MRS command 316 at the control lines 318 while the memory device 202 is in a PDA mode, the example command decoder 224 outputs a binary value of one to the multiplexer 504 to cause the multiplexer 504 to select the MRS qualify V_{REF}DQ value 212 for use by the example data receiver 508 to qualify the MRS command 316 based on the voltage level on the data input/output line zero (DQ0) 216. When the example command decoder 224 detects an MRS command 316 to exit the PDA mode (e.g., the memory device 202 enters a non-PDA mode), the example command decoder 224 outputs a binary zero to the multiplexer 504 to cause the multiplexer 504 to select the operational V_{REF}DQ value 214 for use by the example data receiver 508 to receive data on the data bus of the memory device 202 (e.g., during data write operations when the memory device 202 is in the non-PDA mode).

In the illustrated example, the resistor ladder 506 is used by the V_{REF}DQ selection circuit 500 to generate the MRS qualify V_{REF}DQ value 212 and the operational V_{REF}DQ value 214 based on a main voltage supply VDDQ. In the illustrated example of FIG. 5A, the memory device 202 is also provided with the MRS command qualifier 222 of FIG. 2 to qualify MRS commands 316 from the memory controller 302 based on the binary value detected on the data input/output line zero (DQ0). Other elements of the memory device 202 shown in FIG. 2 are omitted from FIG. 5A. However, it is to be understood that such elements are also part of the memory device 202 shown in the illustrated example of FIG. 5A.

In the illustrated example of FIG. 5A, the memory controller 302 programs the MRS qualify V_{REF}DQ value 212 during a non-PDA mode. In this manner, the memory device 202 can subsequently use the MRS qualify V_{REF}DQ value 212 in the PDA mode to qualify subsequent MRS commands 316 from the memory controller 302 during the V_{REF}DQ margining process.

FIG. 5B depicts an example V_{REF}DQ selection circuit 550 that may be used to implement an example MRS qualify V_{REF}DQ single-set technique during a V_{REF}DQ margining process. The example of FIG. 5B involves setting the MRS qualify V_{REF}DQ value 212 once in the V_{REF}DQ mode register 210 after a reset of the memory devices 202. In this manner, the V_{REF}DQ selection circuit 550 can be used to initialize a V_{REF}DQ margining process and perform multiple iterations of the V_{REF}DQ margining process to test different V_{REF}DQ training values 122. The example V_{REF}DQ selection circuit 550 of FIG. 5B can set the MRS qualify V_{REF}DQ value 212 only once between resets of the memory devices 202 because the example MRS qualify V_{REF}DQ range field 402 and the example MRS qualify V_{REF}DQ level field 404 (FIG. 4) of the V_{REF}DQ mode register 210 are not exposed external to the memory devices 202 for access by the memory controller 302. In the illustrated example of FIG. 5B, if a different value for the MRS qualify V_{REF}DQ value 212 needs to be set in the memory devices 202 to properly qualify MRS commands 316, the memory devices 202 must be reset/re-initialized so that the V_{REF}DQ selection circuit 550 can set the different value for the MRS qualify V_{REF}DQ value 212 as described below.

In the illustrated example of FIG. 5B, the V_{REF}DQ selection circuit 550 is provided with an example first-write detector 552 that is configured to detect the first time the memory controller 302 writes a V_{REF}DQ value to the V_{REF}DQ mode register 210 of the memory device 202 after a reset event of the memory device 202. For example, the memory controller 302 may be configured to, after a reset of the memory devices 202, write the MRS qualify V_{REF}DQ value 212 as the first V_{REF}DQ write to the memory devices 202. When the first-write detector 552 detects the first V_{REF}DQ write from the memory controller 302, the first-write detector 552 sets a copy flag to copy the V_{REF}DQ value (e.g., the MRS qualify V_{REF}DQ value 212) from the example data receiver 220 (FIG. 2) to the example MRS qualify V_{REF}DQ range field 402 and the example MRS qualify V_{REF}DQ level field 404 (FIG. 4) of the V_{REF}DQ mode register 210. Any subsequent write of a V_{REF}DQ value by the memory controller 302 is not detected as a first write of a V_{REF}DQ value. As such, any subsequent V_{REF}DQ value write is processed by the memory device 202 as a write of the operational V_{REF}DQ value 214 into the an example V_{REF}DQ training range operational mode field 406 and the example V_{REF}DQ training level operational mode field 408. In this manner, the example V_{REF}DQ selection circuit 550 of FIG. 5B can be used to cycle through different ones of the V_{REF}DQ training values 122 (FIGS. 1B and 1C) as the operational V_{REF}DQ value 214 during a V_{REF}DQ margining process using the MRS qualify V_{REF}DQ single-set technique.

In the illustrated example of FIG. 5B, the V_{REF}DQ selection circuit 550 of FIG. 5B switches between the MRS qualify V_{REF}DQ value 212 and the operational V_{REF}DQ value 214 as the V_{REF}DQ value for use by the memory device 202 based on MRS commands 316 provided by the memory controller 302 (FIG. 3). The example V_{REF}DQ selection circuit 550 is provided with the example command decoder 224 (FIG. 2), the example multiplexer 504, the example resistor ladder 506 and the example data receiver 508. In the illustrated example, when the command decoder 224 detects an MRS command 316 at the control lines 318 while the memory device 202 is in a PDA mode, the example command decoder 224 outputs a binary value of one to the multiplexer 504 to cause the multiplexer 504 to select the MRS qualify V_{REF}DQ value 212 for use by the example data receiver 508 to qualify the MRS command 316 based on the voltage level on the data input/output line zero (DQ0) 216. When the example command decoder 224 detects an MRS command 316 to exit the PDA mode (e.g., the memory device 202 enters a non-PDA mode), the example command decoder 224 outputs a binary zero to the multiplexer 504 to cause the multiplexer 504 to select the operational V_{REF}DQ value 214 for use by the example data receiver 508 to receive data on the data bus of the memory device 202 (e.g., during data write operations when the memory device 202 is in the non-PDA mode).

In the illustrated example, the resistor ladder 506 is used by the V_{REF}DQ selection circuit 550 to generate the MRS qualify V_{REF}DQ value 212 and the operational V_{REF}DQ value 214 based on a main voltage supply VDDQ. In the illustrated example of FIG. 5B, the memory device 202 is also provided with the MRS command qualifier 222 of FIG. 2 to qualify MRS commands 316 from the memory controller 302 based on the binary value detected on the data input/output line zero (DQ0). Other elements of the memory device 202 shown in FIG. 2 are omitted from FIG. 5B. However, it is to be understood that such elements are also part of the memory device 202 shown in the illustrated example of FIG. 5B.

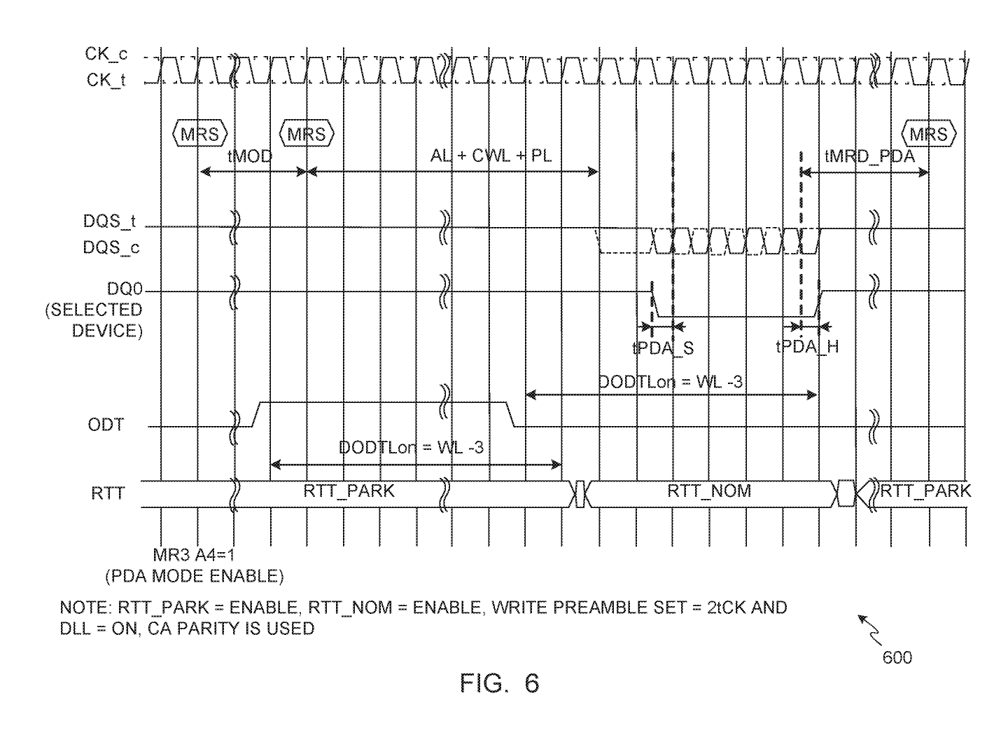

The switching between the MRS qualify V_{REF}DQ value 212 and the operational V_{REF}DQ value 214 of the illustrated examples of FIGS. 5A and 5B may be used in connection with timing requirements defined by the JEDEC Association in JEDEC specification JESD79-4A. An example timing diagram 600 specifying timing requirements for issuing an MRS command 316 to enable the PDA mode is shown in FIG. 6. According to the example timing diagram 600, upon receiving an MRS command 316 to enable the PDA mode via a write to mode register 3 (MR3) (e.g., one of the mode registers 204 of FIG. 2 that is defined in JEDEC specification JESD79-4A to enable the PDA mode), a timing delay of tMOD (Mode Register Set command update delay) should be satisfied before any additional MRS command 316 is issued by the memory controller 302. If the tMOD timing delay is not satisfied, there is a latency of multiple clock cycles (additive latency+CAS (column address strobe) write latency+the parity latency) before the data input/output line zero (DQ0) 216 of the memory device 202 is asserted for selecting the memory device 202.

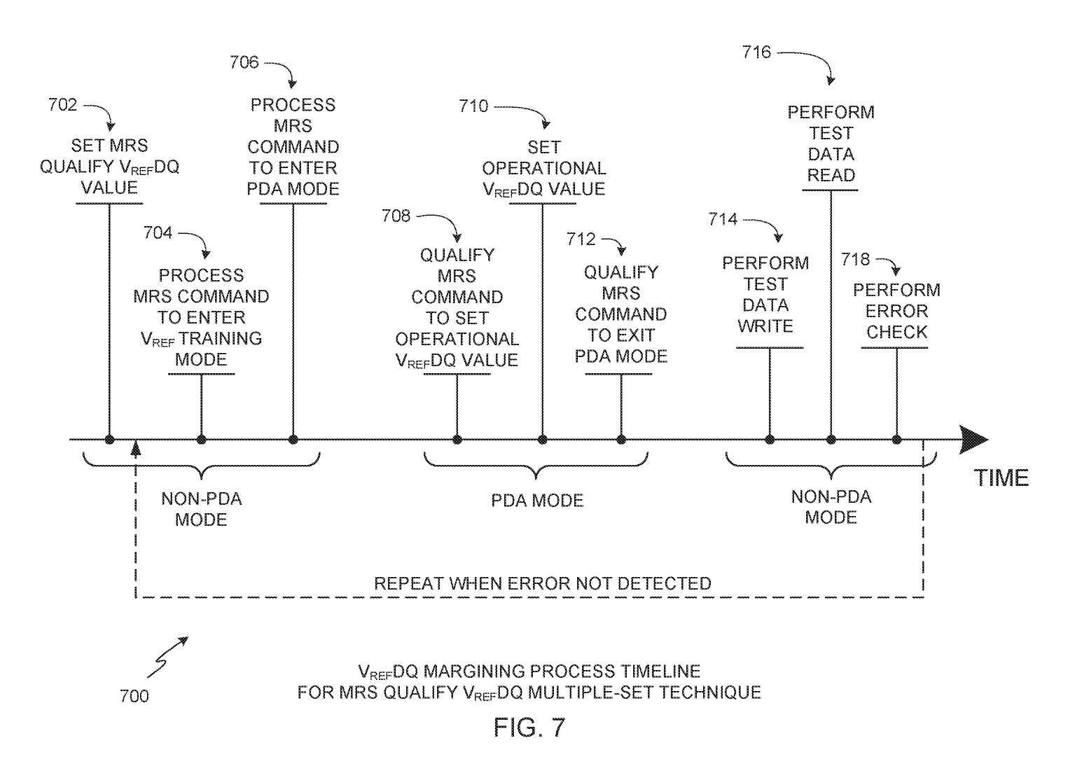

FIG. 7 is an example V_{REF}DQ margining process timeline 700 showing operations for performing a V_{REF}DQ margining process of the example DRAM0-DRAMn memory devices 202. In the illustrated example of FIG. 7, the memory controller 302 sets the MRS qualify V_{REF}DQ value 212 (operation 702) in the V_{REF}DQ mode register 210 (FIG. 2) of the memory device 202 during a non-PDA mode. For example, in the MRS qualify V_{REF}DQ multiple-set technique, the memory device 202 programs the MRS qualify V_{REF}DQ value 212 in the MRS qualify V_{REF}DQ range field 402 and the MRS qualify V_{REF}DQ level field 404 (FIG. 4) as described above in connection with FIG. 5A. In the MRS qualify V_{REF}DQ single-set technique, the memory device 202 programs the MRS qualify V_{REF}DQ value 212 in the MRS qualify V_{REF}DQ range field 402 and the MRS qualify V_{REF}DQ level field 404 as described above in connection with FIG. 5B. In either case, the memory device 202 can use the MRS qualify V_{REF}DQ value 212 in its V_{REF}DQ mode register 210 to qualify subsequent MRS commands 316 issued by the memory controller 302. The MRS qualify V_{REF}DQ value 212 is useful during the PDA mode so that each memory device 202 can qualify MRS commands 316 that are intended to be received by that memory device 202 without qualifying MRS commands 316 that are intended to be received by others of the memory devices 202. In the illustrated example, the non-PDA mode enables writing data to the memory devices 202 and reading data from the memory devices 202.

The memory device 202 processes an MRS command 316 from the memory controller 302 to enter a V_{REF} training mode (operation 704). The V_{REF} training mode enables the memory controller 302 to test a V_{REF}DQ training value 122 (FIGS. 1B and 1C) on the memory device 202 for use as the operational V_{REF}DQ value 214. The memory device 202 also processes an MRS command to enter a PDA mode (e.g., a PDA-enable MRS command) (operation 706). The PDA mode enables the memory controller 302 to target different V_{REF}DQ training values 122 to different ones of the DRAM0-DRAMn memory devices 202 exclusive of others of the DRAM0-DRAMn memory devices 202 to find a different optimal operational V_{REF}DQ value 214 for each of the memory devices 202.

During the PDA mode, the memory device 202 receives and qualifies an MRS command 316 from the memory controller 302 to set the operational V_{REF}DQ value 214 (operation 708). For example, the memory controller 302 uses the MRS command 316 to selectively target the memory device 202 to set the operational V_{REF}DQ value 214 based on a V_{REF}DQ training value (e.g., a V_{REF}DQ training value 122 of FIGS. 1B and 1C) that is to be used to test for a V_{REF}DQ margin. In the illustrated example, the memory device 202 qualifies the MRS command 316 by detecting a binary value of zero at its data input/output line zero (DQ0) 216 (FIG. 2) using the MRS qualify V_{REF}DQ value 212. That is, the memory device 202 confirms that the MRS command 316 is intended to be processed by the memory device 202 based on detecting a binary zero at its data input/output line zero (DQ0) 216. After the memory device 202 qualifies the MRS command 316, the memory devices 202 sets the operational V_{REF}DQ value 214 (operation 710) in the V_{REF}DQ mode register 210. For example, the memory device 202 programs the operational V_{REF}DQ value 214 in the V_{REF}DQ training range operational mode field 406 and the V_{REF}DQ training level operational mode field 408 of the V_{REF}DQ mode register 210.

The memory device 202 receives and qualifies an MRS command 316 to exit the PDA mode (e.g., a PDA-disable mode) (operation 712). For example, the memory controller 302 disables the PDA mode, and enables the non-PDA mode to enable writing and reading data to test the operational V_{REF}DQ value 214 for the memory device 202. During the non-PDA mode, the memory controller 302 controls the memory device 202 to perform a test data write operation (operation 714) and a test data read operation (operation 716). The memory controller 302 then performs an error check (operation 718) based on the write and read operations to determine whether a V_{REF}DQ margin has been reached. For example, if the V_{REF}DQ margining process is being performed to find the maximum V_{REF}DQ margin 126 (FIG. 1C), the maximum V_{REF}DQ margin 126 is reached when the test data write operation 714 writes a binary one to a memory location and the test data read operation 716 reads back a non-matching value of binary zero from the same memory location (e.g., an error is detected). If, for example, the V_{REF}DQ margining process is being performed to find the minimum V_{REF}DQ margin 126, the minimum V_{REF}DQ margin 126 is reached when the test data write operation 714 writes a binary zero to a memory location and the test data read operation 716 reads back a non-matching value of binary one from the same memory location (e.g., an error is detected).

In the illustrated example, when an error is not detected at operation 718 (e.g., a V_{REF}DQ margin is not found) the process of testing another V_{REF}DQ training value 122 as the operational V_{REF}DQ value 214 repeats to test a next incremented or decremented V_{REF}DQ training value 122. In this manner, the V_{REF}DQ margining process is repeated until a V_{REF}DQ margin is reached (e.g., the maximum V_{REF}DQ margin 126 or the minimum V_{REF}DQ margin 128).

While example manners of implementing the memory devices 202 are illustrated in FIGS. 2, 3, 5A, and 5B, and an example manner of implementing the example memory controller 302 is illustrated in FIG. 3, one or more of the elements, processes and/or devices illustrated in FIGS. 2, 3, 5A, and/or 5B may be combined, divided, re-arranged, omitted, eliminated and/or implemented in any other way. Further, the example MRS command qualifier 222, the example command decoder 224, the example mode register interface 226, the example memory mode selector 304, the example memory device selector 306, the example voltage controller 308, the example MRS command generator 310, the example memory interface 312, the example comparator 314, the example first-write detector 552, and/or, more generally, the example memory devices 202 and/or the example memory controller 302 of FIGS. 2, 3, 5A, and/or 5B may be implemented by hardware, software, firmware and/or any combination of hardware, software and/or firmware. Thus, for example, any of the example MRS command qualifier 222, the example command decoder 224, the example mode register interface 226, the example memory mode selector 304, the example memory device selector 306, the example voltage controller 308, the example MRS command generator 310, the example memory interface 312, the example comparator 314, the example first-write detector 552, and/or, more generally, the example memory devices 202 and/or the example memory controller 302 could be implemented by one or more analog or digital circuit(s), logic circuits, programmable processor(s), application specific integrated circuit(s) (ASIC(s)), programmable logic device(s) (PLD(s)) and/or field programmable logic device(s) (FPLD(s)). When reading any of the apparatus or system claims of this patent to cover a purely software and/or firmware implementation, at least one of the example MRS command qualifier 222, the example command decoder 224, the example mode register interface 226, the example memory mode selector 304, the example memory device selector 306, the example voltage controller 308, the example MRS command generator 310, the example memory interface 312, and/or the example comparator 314, the example first-write detector 552, is/are hereby expressly defined to include a tangible computer readable storage device or storage disk such as a memory, a digital versatile disk (DVD), a compact disk (CD), a Blu-ray disk, etc. storing the software and/or firmware. Further still, the memory devices 202 and/or the example memory controller 302 may include one or more elements, processes and/or devices in addition to, or instead of, those illustrated in FIGS. 2, 3, 5A, and 5B, and/or may include more than one of any or all of the illustrated elements, processes and devices.

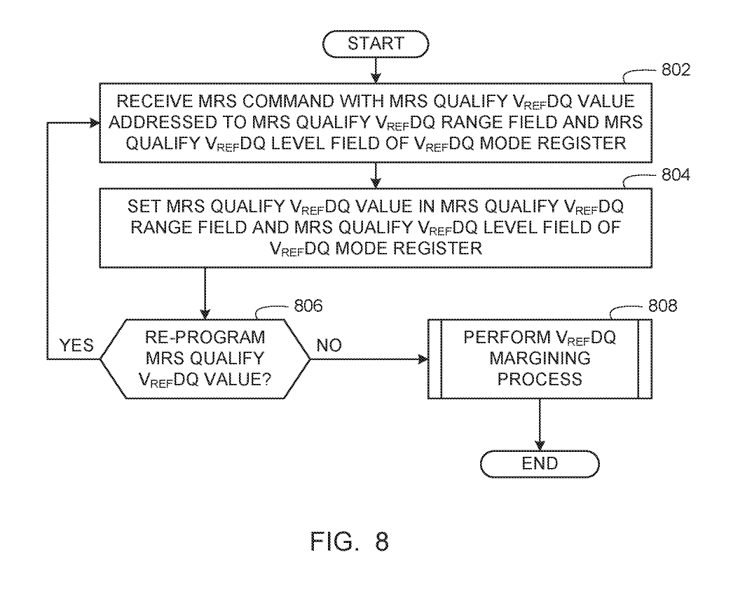

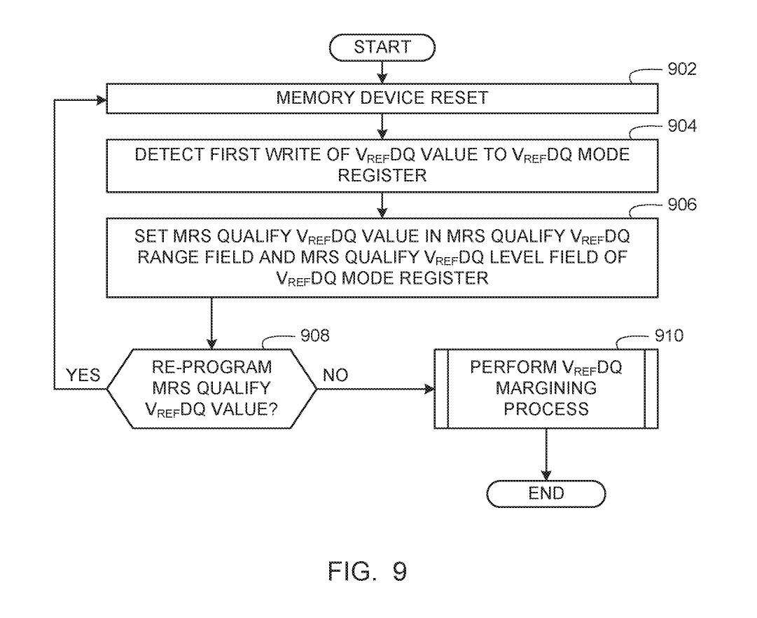

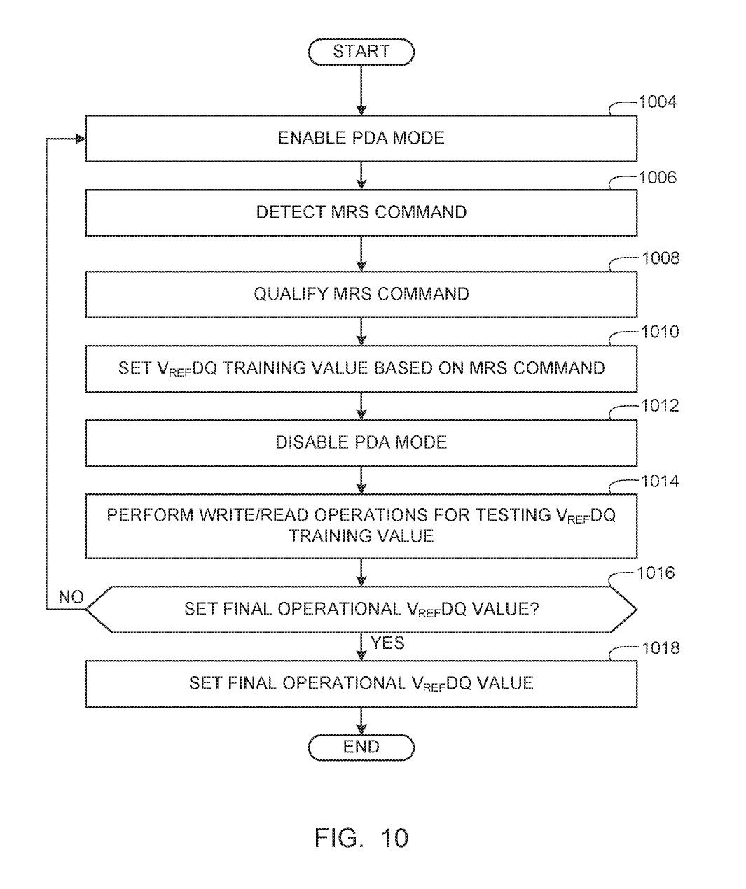

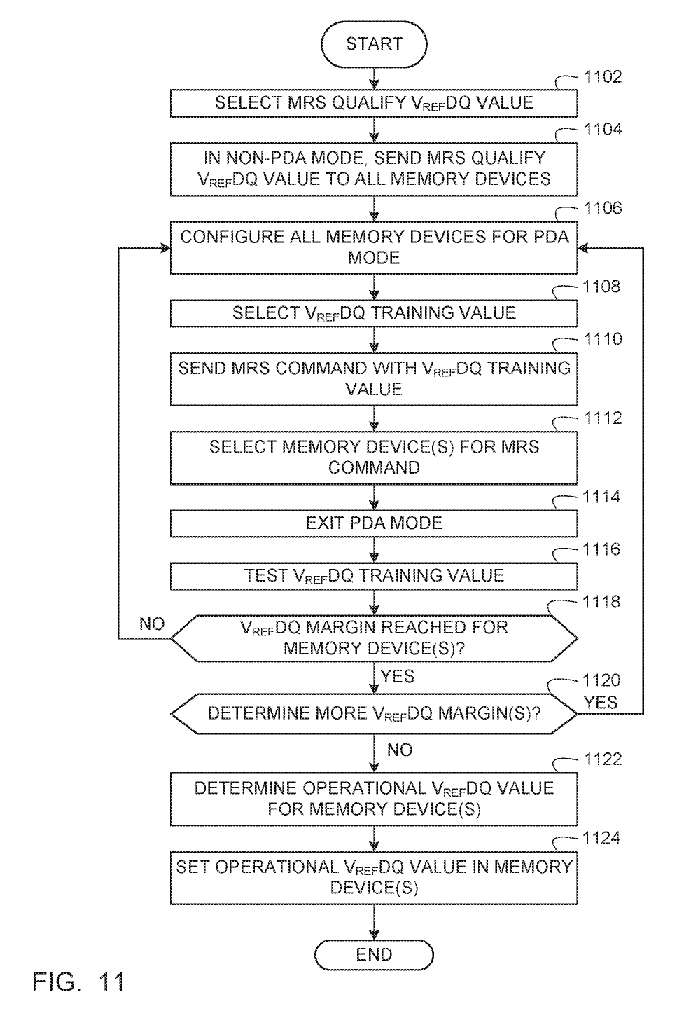

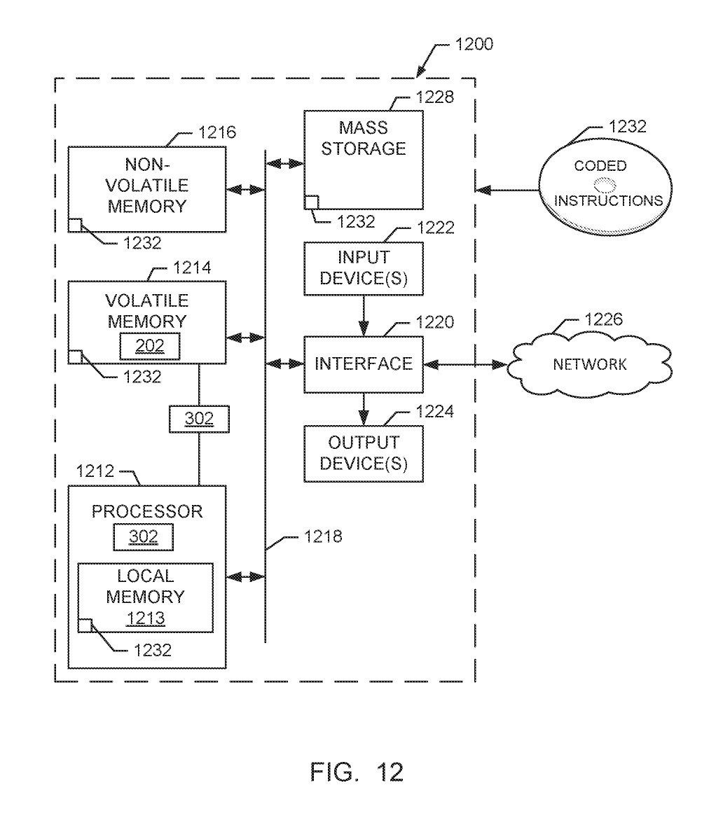

FIG. 8 is a flow diagram representative of an example process that may be used to program an MRS qualify V_{REF}DQ value 212 in the memory devices 202 of FIGS. 2, 3, and 5A using a MRS qualify V_{REF}DQ multiple-set technique. FIG. 9 is a flow diagram representative of an example process that may be used to program an MRS qualify V_{REF}DQ value 212 in the memory devices of FIGS. 2, 3, and 5B using a MRS qualify V_{REF}DQ single-set technique. FIG. 10 is a flow diagram representative of an example process that may be executed to implement the example memory devices 202 of FIGS. 2, 3, 5A, and 5B in accordance with teachings of this disclosure to configure operational V_{REF}DQ values for use by the example memory devices 202 to detect logic levels based on voltages applied to data lines of the memory devices 202. FIG. 11 is a flow diagram representative of an example process that may be executed to implement the example memory controller 302 of FIG. 3 in accordance with teachings of this disclosure to configure operational V_{REF}DQ values in the example memory devices 202 of FIGS. 2, 3, 5A, and 5B. In some examples, the flow diagrams of FIGS. 8, 9, 10, and/or 11 are machine readable instructions that implement programs for execution by the memory devices 202, the memory controller 302, and/or a processor such as the processor 1212 shown in the example processor platform 1200 discussed below in connection with FIG. 12. The programs may be embodied in software stored on a tangible computer readable storage medium such as a CD-ROM, a floppy disk, a hard drive, a digital versatile disk (DVD), a Blu-ray disk, or a memory associated with the memory devices 202, the memory controller 302, and/or the processor 1212, but the entirety of the programs and/or parts thereof could alternatively be executed by one or more devices other than the memory devices 202, the memory controller 302, and/or the processor 1212 and/or embodied in firmware or dedicated hardware. Further, although the example processes and/or programs are described with reference to the flowcharts illustrated in FIGS. 8, 9, 10, and/or 11, many other methods of implementing the example memory devices 202 and/or the example memory controller 302 may alternatively be used. For example, the order of execution of the blocks may be changed, and/or some of the blocks described may be changed, eliminated, or combined.

As mentioned above, the example processes of FIGS. 8, 9, 10, and/or 11 may be implemented using coded instructions (e.g., computer and/or machine readable instructions) stored on a tangible computer readable storage medium such as a hard disk drive, a flash memory, a read-only memory (ROM), a compact disk (CD), a digital versatile disk (DVD), a cache, a random-access memory (RAM) and/or any other storage device or storage disk in which information is stored for any duration (e.g., for extended time periods, permanently, for brief instances, for temporarily buffering, and/or for caching of the information). As used herein, the term tangible computer readable storage medium is expressly defined to include any type of computer readable storage device and/or storage disk and to exclude propagating signals and to exclude transmission media. As used herein, “tangible computer readable storage medium” and “tangible machine readable storage medium” are used interchangeably. Additionally or alternatively, the example processes of FIGS. 8, 9, 10, and/or 11 may be implemented using coded instructions (e.g., computer and/or machine readable instructions) stored on a non-transitory computer and/or machine readable medium such as a hard disk drive, a flash memory, a read-only memory, a compact disk, a digital versatile disk, a cache, a random-access memory and/or any other storage device or storage disk in which information is stored for any duration (e.g., for extended time periods, permanently, for brief instances, for temporarily buffering, and/or for caching of the information). As used herein, the term non-transitory computer readable medium is expressly defined to include any type of computer readable storage device and/or storage disk and to exclude propagating signals and to exclude transmission media. As used herein, when the phrase “at least” is used as the transition term in a preamble of a claim, it is open-ended in the same manner as the term “comprising” is open ended.

The example process of FIG. 8 may be used to implement the example MRS qualify V_{REF}DQ multiple-set technique described above in connection with FIG. 5A to program the MRS qualify V_{REF}DQ value 212 in the example MRS qualify V_{REF}DQ range field 402 and the example MRS qualify V_{REF}DQ level field 404 (FIG. 4) of the V_{REF}DQ mode register 210 (FIGS. 2 and 4) based on the MRS qualify V_{REF}DQ range field 402 and the MRS qualify V_{REF}DQ level field 404 being exposed external to the memory device 202 for direct access by the memory controller 302. The example process of FIG. 8 is described as being performed by one memory device 202 (e.g., the DRAM0 memory device 202 of FIGS. 2, 3, and 5A). However, the example process of FIG. 8 may be performed by any number of memory devices 202 at the same time or in serial fashion.

The example process of FIG. 8 begins at block 802 at which the example command decoder 224 (FIGS. 2 and 5A) receives an MRS command 316 with an MRS qualify V_{REF}DQ value 212 addressed to the MRS qualify V_{REF}DQ range field 402 and the example MRS qualify V_{REF}DQ level field 404 during a non-PDA mode. The example mode register interface 226 (FIG. 2) programs or sets the MRS qualify V_{REF}DQ value 212 in the MRS qualify V_{REF}DQ range field 402 and the example MRS qualify V_{REF}DQ level field 404 (block 804). The command decoder 224 then determines whether the MRS qualify V_{REF}DQ value 212 needs to be re-programmed (block 806). For example, the memory controller 302 may send a subsequent MRS command 316 instructing the memory device 202 to re-program the MRS qualify V_{REF}DQ value 212 if the memory controller 302 determines that the memory device 202 (or any of the other memory devices 202) is not correctly responding to MRS commands (e.g., the memory device(s) 202 is/are not correctly qualifying MRS commands 316 based on the previously set MRS qualify V_{REF}DQ value 212). If the command decoder 224 determines at block 806 that the MRS qualify V_{REF}DQ value 212 needs to be re-programmed, control returns to block 802 at which the MRS qualify V_{REF}DQ value 212 can be re-programmed in the V_{REF}DQ mode register 210 without needing to reset/re-initialize the memory device 202. Otherwise, if the command decoder 224 determines at block 806 that the MRS qualify V_{REF}DQ value 212 does not need to be re-programmed, control advances to block 808 at which the memory device 202 performs a V_{REF}DQ margining process. In the illustrated example, the V_{REF}DQ margining process of block 808 may be implemented using the example process described below in connection with FIG. 10. The example process of FIG. 8 then ends.

The example process of FIG. 9 may be used to implement the MRS qualify V_{REF}DQ single-set technique described above in connection with FIG. 5B to program the MRS qualify V_{REF}DQ value 212 in the example MRS qualify V_{REF}DQ range field 402 and the example MRS qualify V_{REF}DQ level field 404 of the V_{REF}DQ mode register 210 (FIG. 2) based on the MRS qualify V_{REF}DQ range field 402 and the MRS qualify V_{REF}DQ level field 404 not being exposed external to the memory device 202 for direct access by the memory controller 302. The example process of FIG. 9 is described as being performed by one memory device 202 (e.g., the DRAM0 memory device 202 of FIGS. 2, 3, and 5B). However, the example process of FIG. 9 may be performed by any number of memory devices 202 at the same time or in serial fashion.

The example process of FIG. 9 begins at block 902 at which the memory device 202 undergoes a reset. The memory device reset may be from a cold boot state upon power up of an electronic device in which the memory device is located. Alternatively, the memory device reset may be from a reset of the memory device 202 while the electronic device is operating without resetting other components of the electronic device in which the memory device 202 is located. The example first-write detector 552 (FIG. 5B) detects a first write of a V_{REF}DQ value to the V_{REF}DQ mode register 210 (FIGS. 2 and 4) (block 904). For example, following the memory device reset of block 902, the memory controller 302 sends an MRS command 316 to the memory device 202 (and the other memory devices 202 of FIG. 2) to program the MRS qualify V_{REF}DQ value 212 as the first V_{REF}DQ value write to the memory device 202. The example mode register interface 226 (FIG. 2) programs or sets the MRS qualify V_{REF}DQ value 212 in the MRS qualify V_{REF}DQ range field 402 and the example MRS qualify V_{REF}DQ level field 404 (block 906). For example, when the first-write detector 552 detects the first V_{REF}DQ value write, the first-write detector 552 can set a copy flag. In this manner, after the command decoder 224 decodes the MRS command 316 (containing the MRS qualifying V_{REF}DQ value 212) and detects the copy flag, the example mode register interface 226 copies the MRS qualify V_{REF}DQ value 212 from the data receiver 220 and programs it into the MRS qualify V_{REF}DQ range field 402 and the example MRS qualify V_{REF}DQ level field 404.

The command decoder 224 then determines whether the MRS qualify V_{REF}DQ value 212 needs to be re-programmed (block 908). For example, the memory controller 302 may send a subsequent reset command to reset the memory device 202. In such examples, the memory controller 302 may use the reset command to subsequently re-program a different MRS qualify V_{REF}DQ value 212 if the memory controller 302 determines that the memory device 202 (or any of the other memory devices 202) is not correctly responding to MRS commands (e.g., the memory device(s) 202 is/are not correctly qualifying MRS commands 316 based on the previously set MRS qualify V_{REF}DQ value 212). If the command decoder 224 determines at block 908 that the MRS qualify V_{REF}DQ value 212 needs to be re-programmed, control returns to block 902 at which the memory device 202 undergoes a device reset so that the memory controller 302 can subsequently program a different MRS qualify V_{REF}DQ value 212 in the V_{REF}DQ mode register 210. Otherwise, if the command decoder 224 determines at block 908 that the MRS qualify V_{REF}DQ value 212 does not need to be re-programmed, control advances to block 910 at which the memory device 202 performs a V_{REF}DQ margining process. In the illustrated example, V_{REF}DQ margining process of block 910 may be implemented using the example process described below in connection with FIG. 10. The example process of FIG. 9 then ends.

The example process of FIG. 10 is a V_{REF}DQ margining process to configure operational V_{REF}DQ values for use by the example memory devices 202. The example process of FIG. 10 may be used to implement the V_{REF}DQ margining process of block 808 of FIG. 8 when the MRS qualify V_{REF}DQ value 212 is programmed using the example MRS qualify V_{REF}DQ multiple-set technique described above in connection with FIGS. 5A and 8. Additionally or alternatively, the example process of FIG. 10 may be used to implement the V_{REF}DQ margining process of block 910 of FIG. 9 when the MRS qualify V_{REF}DQ value 212 is programmed using the example MRS qualify V_{REF}DQ single-set technique as described above in connection with FIGS. 5B and 9. The example process of FIG. 10 is described as being performed by one memory device 202 (e.g., the DRAM0 memory device 202 of FIGS. 2, 3, 5A, and 5B). However, the example process of FIG. 10 may be performed by any number of memory devices 202 at the same time or in serial fashion.

The example process of FIG. 10 begins at block 1004, at which the example mode register interface 226 (FIG. 2) enables the PDA mode (block 1004). For example, the command decoder 224 (FIGS. 2, 5A, and 5B) may decode a PDA-enable register setting in an MRS command 316 received from the memory controller 302, which causes the mode register interface 226 to set a PDA mode enable bit in one of the mode registers 204 (FIG. 2). For example, JEDEC standard JESD79-4A defines the PDA mode enable bit as being located in a mode register 3 (MR3) of the mode registers 204 (FIG. 2). In other examples, the PDA mode enable bit may be located in any other register.

The example command decoder 224 detects an MRS command 316 (block 1006). For example, an MRS command 316 from the memory controller 302 is received on the control lines 318 and/or the address bus 320 (FIG. 3) in-circuit with the memory device 202. The example MRS command qualifier 222 (FIGS. 2, 5A, and 5B) qualifies the MRS command 316 (block 1008). For example, the MRS command qualifier 222 qualifies the MRS command 316 as intended to be received and processed by the memory device 202 based on the binary value at the data input/output line zero 216 (FIGS. 2, 5A, and 5B). The example mode register interface 226 sets a V_{REF}DQ training value 122 (FIGS. 1B and 1C) based on the MRS command 316 (block 1010). In the illustrated example, the MRS command qualified at block 1008 is an MRS command in which the memory controller 302 provides the V_{REF}DQ training value 122. In the illustrated example, the example mode register interface 226 sets the V_{REF}DQ training value 122 in the V_{REF}DQ training range operational mode field 406 and the V_{REF}DQ training level operational mode field 408 of the V_{REF}DQ mode register 210 for use in performing the V_{REF}DQ margining process.

The example mode register interface 226 disables the PDA mode (block 1012). For example, the command decoder 224 decodes a PDA-disable MRS command from the memory controller 302 and the example mode register interface 226 updates a corresponding one of the mode registers 204 to disable the PDA mode. As such, the memory device 202 begins operating in a non-PDA mode. The memory device 202 performs write and read operations for testing of the V_{REF}DQ training value 122 (block 1014). For example, if the V_{REF}DQ margining process is being used to find a maximum V_{REF}DQ margin (e.g., the maximum V_{REF}DQ margin 126 of FIG. 1C), the memory device 202 receives a write operation from the memory controller 302 to store a binary value of one in the memory device 202, and also receives a read operation to read back the stored value. Reading back the stored value as a binary one enables the memory controller 302 to determine that the maximum V_{REF}DQ margin 126 has not been reached (e.g., an error has not been detected at the error check of operation 718 of FIG. 7), and reading back the stored value as a binary zero enables the memory controller 302 to determine that the maximum V_{REF}DQ margin 126 has been reached (e.g., an error has been detected at the error check of operation 718 of FIG. 7). Alternatively, if the V_{REF}DQ margining process is being used to find a minimum V_{REF}DQ margin (e.g., the minimum V_{REF}DQ margin 128 of FIG. 1C), the memory device 202 receives a write operation from the memory controller 302 to store a binary value of zero in the memory device 202, and also receives a read operation to read back the stored value. Reading back the stored value as a binary zero enables the memory controller 302 to determine that the minimum V_{REF}DQ margin 128 has not been reached (e.g., an error has not been detected at the error check of operation 718 of FIG. 7), and reading back the stored value as a binary one enables the memory controller 302 to determine that the minimum V_{REF}DQ margin 128 has been reached (e.g., an error has not been detected at the error check of operation 718 of FIG. 7).

The command decoder 224 determines whether to set a final operational V_{REF}DQ value 214 (block 1016). For example, when the memory controller 302 determines that it has found both the maximum V_{REF}DQ margin 126 and the minimum V_{REF}DQ margin 128, the memory controller 302 determines the final operational V_{REF}DQ value 214 (FIG. 2) as a voltage between the maximum V_{REF}DQ margin 126 and the minimum V_{REF}DQ margin 128. The memory device 202 then receives the final operational V_{REF}DQ value 214 from the memory controller 302. In some examples, the final operational V_{REF}DQ value 214 is the optimal V_{REF}DQ value 130 (FIG. 1C) selected by the memory controller 302 to be located between the maximum V_{REF}DQ margin 126 and the minimum V_{REF}DQ margin 128 to produce the smallest BER (or an acceptable BER) for data written to the memory device 202. In the illustrated example, control advances to block 1018 when the command decoder 224 determines, at block 1016, that a final operational V_{REF}DQ value 214 is to be set based on receiving an MRS command that includes the final operational V_{REF}DQ value 214 and that instructs the memory device 202 to set the final operational V_{REF}DQ value 214 in a corresponding one of the mode registers 204. At block 1018, the mode register interface 226 sets the final operational V_{REF}DQ value.

Otherwise, if the command decoder 224 does not receive a final operational V_{REF}DQ value 214, the memory controller 302 has not yet found both the maximum V_{REF}DQ margin 126 and the minimum V_{REF}DQ margin 128 of the memory device 202 and must continue performing the V_{REF}DQ margining process on the memory device 202. As such, when the command decoder 224 determines, at block 1016, that a final operational V_{REF}DQ value 214 is not yet available to be set, control returns to block 1004 to perform another iteration of the V_{REF}DQ margining process based on another V_{REF}DQ training value 122. In this manner, the V_{REF}DQ margining process of FIG. 10 may be performed a number of times until a final operational V_{REF}DQ value is received from the memory controller 302. When the final operational V_{REF}DQ value is set at block 1018, the example process of FIG. 10 ends.

The example process of FIG. 11 may be used to implement the memory controller 302 to perform a V_{REF}DQ margining process to configure operational V_{REF}DQ values for use by the example memory devices 202. The example process of FIG. 11 may be used to implement V_{REF}DQ margining processes based on the example MRS qualify V_{REF}DQ multiple-set technique for setting the MRS qualify V_{REF}DQ value 212 described above in connection with FIGS. 5A and 8. Additionally or alternatively, the example process of FIG. 11 may be used to implement V_{REF}DQ margining processes based on the example MRS qualify V_{REF}DQ single-set technique for setting the MRS qualify V_{REF}DQ value 212 described above in connection with FIGS. 5B and 9. The example process of FIG. 11 is described as being performed by the memory controller 302 of FIG. 3 in association with the memory device 202 of FIGS. 2, 3, 5A, and 5B. However, the example process of FIG. 11 may be performed by the memory controller 302 (or any other memory controller) in association with any number of memory devices at the same time or in serial fashion.

The example process of FIG. 11 begins at block 1102 at which the voltage controller 308 (FIG. 3) selects the MRS qualify V_{REF}DQ value 212 (block 1102). For example, the voltage controller 308 accesses the MRS qualify V_{REF}DQ register 313 (FIG. 3) to obtain the MRS qualify V_{REF}DQ value 212 that all of the memory devices 202 are able to use to successfully qualify MRS commands 316 (FIG. 3). When the memory device 202 is in the non-PDA mode, the memory interface 312 (FIG. 3) of the memory controller 302 sends the MRS qualify V_{REF}DQ value 212 to all memory devices 202 (block 1104). That is, the memory interface 312 sends the MRS qualify V_{REF}DQ value 212 for programming in all the memory devices 202 of the memory module 200 (FIGS. 2 and 3) so that all the memory devices 202 use the same MRS qualify V_{REF}DQ value 212 for qualifying MRS commands in the PDA mode. The operations of blocks 902 and 904 may be performed by the memory controller 302 based on the MRS qualify V_{REF}DQ multiple-set technique or the MRS qualify V_{REF}DQ single-set technique.

The example memory mode selector 304 (FIG. 3) configures all memory devices 202 of the memory module 200 to operate in PDA mode (block 1106). For example, the PDA mode is used to perform the V_{REF}DQ margining process so that each of the memory devices 202 can be individually selected to program V_{REF}DQ training values 122 therein to determine maximum V_{REF}DQ margins 126 and minimum V_{REF}DQ margins 128.

The example voltage controller 308 (FIG. 3) selects a V_{REF}DQ training value 122 (block 1108). For example, the voltage controller 308 selects a V_{REF}DQ training value 122 to determine a maximum V_{REF}DQ margin 126 or a minimum V_{REF}DQ margin 128. If the memory controller 302 has already tested a previous V_{REF}DQ training value 122, and this is a subsequent iteration to test a next V_{REF}DQ training value 122, the voltage controller 308 selects a next incremented/decremented V_{REF}DQ training value 122. For example, if the memory controller 302 is determining a maximum V_{REF}DQ margin 126, the voltage controller 308 selects a next incremented V_{REF}DQ training value 122 at block 1108. If, for example, the memory controller 302 is determining a minimum V_{REF}DQ margin 128, the voltage controller 308 selects a next decremented V_{REF}DQ training value 122 at block 1108.

The example MRS command generator 310 (FIG. 3) sends an MRS command 316 with the selected V_{REF}DQ training value 122 (block 1110). For example, the MRS command generator 310 generates the MRS command 316 to include the V_{REF}DQ training value 122 selected at block 1108, and sends the MRS command 316 with the V_{REF}DQ training value 122 via the memory interface 312 (FIG. 3). The example memory device selector 306 (FIG. 3) selects one or more of the memory device(s) 202 that is/are the intended target(s) for the MRS command 316 (block 1112). For example, the memory controller 302 may test the selected V_{REF}DQ training value 122 on one or more of the memory device(s) 202. The example memory mode selector 304 causes the memory device(s) 202 to exit the PDA mode (block 1114). For example, the memory mode selector 304 exits the PDA mode by causing the MRS command generator 310 to generate an MRS command 316 specifying that the PDA mode is disabled and causes the memory interface 312 to send the PDA-disable MRS command 316 to the memory device(s) 202.

The example memory controller 302 tests the V_{REF}DQ training value 122 (block 1116). For example, the memory controller 302 controls the memory devices 202 to perform write and read operations to compare read back values to written binary test values. That is, first the memory controller 302 sends a write command to the memory devices 202 to write a binary test value corresponding to the V_{REF}DQ margin for which the memory controller 302 is testing. For example, if the memory controller 302 is determining a maximum V_{REF}DQ margin 126, the memory controller 302 writes a binary test value of one to the memory devices 202. If, for example, the memory controller 302 is determining a minimum V_{REF}DQ margin 128, the memory controller 302 writes a binary test value of zero to the memory devices 202. After writing the binary test value, the memory controller 302 sends a read command to the memory devices 202 to read back the stored values. In this manner, the memory controller 302 can use the stored values read back from the memory devices 202 to determine whether a maximum V_{REF}DQ margin 126 or the minimum V_{REF}DQ margin 128 has been reached.

The example comparator 314 (FIG. 3) determines whether a V_{REF}DQ margin has been reached for the selected memory devices 202 (block 1118). For example, if the memory controller 302 is testing for a maximum V_{REF}DQ margin 126, the comparator 314 determines whether stored binary values read from the memory devices 202 match a binary test value of one previously written to the memory devices 202. If, for example, the memory controller 302 is testing for a minimum V_{REF}DQ margin 128, the comparator 314 determines whether a stored binary value read from the memory devices 202 matches a binary test value of zero previously written to the memory devices 202. When the example comparator 314 finds a match (e.g., an error has not been detected at the error check of operation 718 of FIG. 7), a V_{REF}DQ margin has not been reached.

When the example comparator 314 determines at block 1118 that a V_{REF}DQ margin has not been reached, control returns to block 1106 to test a next decremented/incremented V_{REF}DQ training value 122 as the operational V_{REF}DQ value 214. When the example comparator 314 determines at block 1118 that a V_{REF}DQ margin has been reached, control advances to block 1120 at which the memory controller 302 determines whether any one or more additional V_{REF}DQ margin(s) is/are to be determined. For example, the voltage controller 308 may determine whether a maximum V_{REF}DQ margin 126 and/or a minimum V_{REF}DQ margin 128 has yet to be determined for one or more memory devices 202 to enable the voltage controller 308 to determine operational V_{REF}DQ values 214 for all of the memory devices 202 of the memory module 200 (FIGS. 2 and 3).

When the memory controller 302 determines at block 1120 that one or more V_{REF}DQ margins are to be determined, control returns to block 1106 to perform the V_{REF}DQ margining process to determine the one or more additional V_{REF}DQ margins. When the memory controller 302 determines at block 1120 that no more V_{REF}DQ margins are to be determined, the voltage controller 308 determines the operational V_{REF}DQ values 214 for the memory devices 202 (block 1122). For example, the voltage controller 308 determines the operational V_{REF}DQ values 214 for each memory device 202 to be an optimal V_{REF}DQ value (e.g., the optimal V_{REF}DQ value 130 of FIG. 1C) between the maximum V_{REF}DQ margin 126 and the minimum V_{REF}DQ margin 128 that achieves an acceptable BER for that memory device 202.

The memory controller 302 sets the operational V_{REF}DQ values in the corresponding memory devices 202 (block 1124). For example, the memory mode selector 304 can put the memory devices 202 in PDA mode, and the MRS command generator 310 can send MRS commands 316 and corresponding operational V_{REF}DQ values 214 to respective ones of the memory devices 202. In this manner, each of the memory devices 202 can program its corresponding one of the operational V_{REF}DQ values 214 in a corresponding mode register 204 (FIG. 2) for use during a non-PDA mode. The example process of FIG. 11 then ends.

FIG. 12 is an example processor platform capable of executing the example computer readable instructions represented by FIGS. 8, 9, 10, and/or 11 to implement the example memory devices 202 of FIGS. 2, 3, 5A, and 5B, the memory module 200 of FIGS. 2 and 3, and/or the memory controller 302 of FIG. 3 to implement example V_{REF}DQ margining processes in accordance with the teachings of this disclosure. The processor platform 1200 can be, for example, a server, a personal computer, a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, or any other type of computing device.

The processor platform 1200 of the illustrated example includes a processor 1212. The processor 1212 of the illustrated example is hardware. For example, the processor 1212 can be implemented by one or more integrated circuits, logic circuits, microprocessors or controllers from any desired family or manufacturer.

The processor 1212 of the illustrated example includes a local memory 1213 (e.g., a cache). The processor 1212 of the illustrated example is in communication with a main memory including a volatile memory 1214 and a non-volatile memory 1216 via a bus 1218. The volatile memory 1214 may be implemented by Synchronous Dynamic Random Access Memory (SDRAM), Dynamic Random Access Memory (DRAM), RAMBUS Dynamic Random Access Memory (RDRAM) and/or any other type of random access memory device. The non-volatile memory 1216 may be implemented by flash memory and/or any other desired type of memory device. Access to the main memory 1214, 1216 is controlled by one or more memory controllers. In the illustrated example of FIG. 12, the memory controller 302 may be implemented in the processor 1212 and/or may be implemented separate from the processor 1212. Also in the illustrated example, the memory devices 202 may be implemented in the volatile memory 1214. In some examples, the memory devices 202 and the memory controller 302 may be fabricated and/or packaged in the same volatile memory 1214.

The processor platform 1200 of the illustrated example also includes an interface circuit 1220. The interface circuit 1220 may be implemented by any type of interface standard, such as an Ethernet interface, a universal serial bus (USB), and/or a PCI express interface.

In the illustrated example, one or more input devices 1222 are connected to the interface circuit 1220. The input device(s) 1222 permit(s) a user to enter data and commands into the processor 1212. The input device(s) can be implemented by, for example, an audio sensor, a microphone, a camera (still or video), a keyboard, a button, a mouse, a touchscreen, a track-pad, a trackball, isopoint and/or a voice recognition system.

One or more output devices 1224 are also connected to the interface circuit 1220 of the illustrated example. The output devices 1224 can be implemented, for example, by display devices (e.g., a light emitting diode (LED), an organic light emitting diode (OLED), a liquid crystal display, a cathode ray tube display (CRT), a touchscreen, a tactile output device, a printer and/or speakers). The interface circuit 1220 of the illustrated example, thus, typically includes a graphics driver card, a graphics driver chip or a graphics driver processor.

The interface circuit 1220 of the illustrated example also includes a communication device such as a transmitter, a receiver, a transceiver, a modem and/or network interface card to facilitate exchange of data with external machines (e.g., computing devices of any kind) via a network 1226 (e.g., an Ethernet connection, a digital subscriber line (DSL), a telephone line, coaxial cable, a cellular telephone system, etc.).

The processor platform 1200 of the illustrated example also includes one or more mass storage devices 1228 for storing software and/or data. Examples of such mass storage devices 1228 include floppy disk drives, hard drive disks, compact disk drives, Blu-ray disk drives, RAID systems, and digital versatile disk (DVD) drives.

Coded instructions 1232 for use by the memory devices 202 and/or the memory controller 302 to implement the example processes of FIGS. 8, 9, 10 and/or 11 may be stored in the non-volatile memory 1216, and/or on a removable tangible computer readable storage medium such as a CD or DVD. In some examples, the coded instructions 1232 are programmed by the processor platform 1200 into the memory devices 202, the memory controller 302, and/or the memory module 200 of FIGS. 2 and 3 during system initialization for use by the memory devices 202, the memory controller 302, and/or the memory module 200 during operation of the processor platform 1200. In other examples, the processor platform 1200 is used during the manufacture of the memory devices 202, the memory controller 302, and/or the memory module 200. In such examples, the processor platform 1200 programs and/or configures the memory devices 202, the memory controller 302, and/or the memory module 200 based on the coded instructions 1232 during a time of manufacture so that the memory devices 202, the memory controller 302, and/or the memory module 200 can be distributed for use in other processor systems.

Examples disclosed herein are useful to perform V_{REF}DQ margining processes using a PDA mode to configure operational V_{REF}DQ levels in memory devices relatively faster and more reliably than prior techniques. Examples disclosed herein substantially reduce or eliminate configuring memory devices with an operational V_{REF}DQ value during a V_{REF}DQ margining process with which the memory devices become unresponsive by being unable to qualify subsequent MRS commands from a memory controller, or become erroneously responsive by qualifying subsequent MRS commands from a memory controller that are not intended for them, due to the operational V_{REF}DQ value being too high or too low. Prior techniques that cause such unresponsiveness or erroneous responsiveness to MRS commands must repeatedly perform a memory initialization procedure to reset the memory devices out of the unresponsive or erroneously responsive state so that the memory devices can continue with the V_{REF}DQ margining process. However, performing the memory initialization procedure repeatedly in such manner produces unfavorable results such as increased boot times of corresponding processor systems because the processor systems must await proper configuration of the memory devices before completing a boot process. Examples disclosed herein decrease boot times of processor systems by using an MRS qualify V_{REF}DQ value separate from an operational V_{REF}DQ value as disclosed herein so that memory devices can use the MRS qualify V_{REF}DQ value to reliably qualify MRS commands so that memory devices do not become unresponsive or erroneously responsive to MRS commands from a memory controller even when an operational V_{REF}DQ value is incremented or decremented with different V_{REF}DQ training values during a V_{REF}DQ margining process.

Examples disclosed herein are useful to improve BER associated with reading memory cells. For example, determining an optimal operational V_{REF}DQ value for each memory device independent of other memory devices in a same memory module increases the accuracy with which each memory device determines binary values based on voltage levels applied at its data bus. In this manner, examples disclosed herein may be used to improve data reliability of memory devices.

The following pertain to further examples disclosed herein.

Example 1 is a method to configure reference voltage values for use with data lines of a memory device. The method of Example 1 includes setting a first reference voltage value in the memory device for use during operation of the memory device in a per-device addressability mode, the first reference voltage value for use by the memory device to determine a first logic value at a data line of the memory device during the per-device addressability mode, the per-device addressability mode to enable access to the memory device exclusive of other memory devices in circuit with the memory device; and setting a second reference voltage value in the memory device for use during operation of the memory device in a non-per-device addressability mode, the non-per-device addressability mode to enable writing data to the memory device, the second reference voltage value for use by the memory device to determine a second logic value at the data line of the memory device during a write operation.

In Example 2, the subject matter of Example 1 can optionally include that the setting of the first and second reference voltage values in the memory device includes storing the first and second reference voltage values in a mode register of the memory device.

In Example 3, the subject matter of any one of Examples 1-2 can optionally include setting the first reference voltage value using a first field of the mode register during the non-per-device addressability mode, and setting the second reference voltage value using a second field of the mode register during the per-device addressability mode.

In Example 4, the subject matter of any one of Examples 1-3 can optionally include, when a reference voltage margin of the memory device is not reached based on the second reference voltage value, overwriting the second reference voltage value in the second field of the mode register without overwriting the first reference voltage value in the first field of the mode register.

In Example 5, the subject matter of any one of Examples 1-4 can optionally include receiving the first reference voltage value at the memory device when the memory device is not in the per-device addressability mode.

In Example 6, the subject matter of any one of Examples 1-5 can optionally include receiving the first reference voltage value at the memory device as part of a command from a memory controller, the command not being exclusive to the memory device, the command also intended to set the first reference voltage value in the other memory devices in circuit with the memory device.

In Example 7, the subject matter of any one of Examples 1-6 can optionally include receiving the second reference voltage value at the memory device as part of a command from a memory controller, the command being intended to be processed by the memory device exclusive of one or more of the other memory devices in circuit with the memory device.

In Example 8, the subject matter of any one of Examples 1-7 can optionally include that the setting of the first and second reference voltage values in the memory device is performed by a memory controller sending corresponding mode register set commands to the memory device.

In Example 9, the subject matter of any one of Examples 1-8 can optionally include that the setting of the first and second reference voltage values in the memory device is performed by the memory device based on receiving corresponding mode register set commands from a memory controller.

Example 10 is a memory device to configure reference voltage values for use with data lines of the memory device. The memory device of Example 8 includes a mode register interface to: set a first reference voltage value in the memory device for use during operation of the memory device in a per-device addressability mode, the first reference voltage value for use by the memory device to determine a first logic value at a data line of the memory device during the per-device addressability mode, the per-device addressability mode to enable access to the memory device exclusive of other memory devices in circuit with the memory device; and set a second reference voltage value in the memory device for use during operation of the memory device in a non-per-device addressability mode, the non-per-device addressability mode to enable writing data to the memory device, the second reference voltage value for use by the memory device to determine a second logic value at the data line of the memory device during a write operation.

In Example 11, the subject matter of Example 10 can optionally include a mode register, the mode register interface to set the first and second reference voltage values in the mode register.

In Example 12, the subject matter of any one of Examples 1-11 can optionally include a first field and a second field of the mode register, the mode register interface to set the first reference voltage value using the first field of the mode register during the non-per-device addressability mode, and the mode register interface to set the second reference voltage value using the second field of the mode register during the per-device addressability mode.

In Example 13, the subject matter of any one of Examples 1-12 can optionally include that the mode register interface is further to, when a reference voltage margin of the memory device is not reached based on the second reference voltage value, overwrite the second reference voltage value using the second field of the mode register without overwriting the first reference voltage value in the first field of the mode register.

In Example 14, the subject matter of any one of Examples 1-13 can optionally include a data receiver to receive the first reference voltage value at the memory device when the memory device is not in the per-device addressability mode.

In Example 15, the subject matter of any one of Examples 1-14 can optionally include a command decoder to receive the first reference voltage value at the memory device as part of a command from a memory controller, the command not being exclusive to the memory device, the command also intended to set the first reference voltage value in the other memory devices in circuit with the memory device.

In Example 16, the subject matter of any one of Examples 1-15 can optionally include a command decoder to receive the second reference voltage value at the memory device as part of a command from a memory controller, the command being intended to be processed by the memory device exclusive of one or more of the other memory devices in circuit with the memory device.

Example 17 is an apparatus including the memory device of any one of Examples 1-16, and further including: one or more processors; a network interface in communication with the one or more processors; and a memory controller in communication with the one or more processors and the memory device, the memory controller to send the first reference voltage value and the second reference voltage value to the memory device.

Example 18 is at least one article of manufacture including machine readable instructions that, when executed, cause a memory controller to at least: set a first reference voltage value in a memory device for use during operation of the memory device in a per-device addressability mode, the first reference voltage value for use by the memory device to determine a first logic value at a data line of the memory device during the per-device addressability mode, the per-device addressability mode to enable access to the memory device exclusive of other memory devices in circuit with the memory device; and set a second reference voltage value in the memory device for use during operation of the memory device in a non-per-device addressability mode, the non-per-device addressability mode to enable writing data to the memory device, the second reference voltage value for use by the memory device to determine a second logic value at the data line of the memory device during a write operation.

In Example 19, the subject matter of Example 18 can optionally include that the setting of the first and second reference voltage values in the memory device includes sending the first and second reference voltage values to the memory device to store in a mode register of the memory device.

In Example 20, the subject matter of any one of Examples 18-19 can optionally include that the instructions are to cause the memory controller to set the first and second reference voltage values in the memory device by sending the first reference voltage value to the memory device during the non-per-device addressability mode to store using a first field of the mode register, and sending the second reference voltage value to the memory device during the per-device addressability mode to store using a second field of the mode register.

In Example 21, the subject matter of any one of Examples 18-20 can optionally include that the instructions are further to cause the memory controller to, when a reference voltage margin of the memory device is not reached based on the second reference voltage value, overwrite the second reference voltage value using the second field of the mode register without overwriting the first reference voltage value in the first field of the mode register.

In Example 22, the subject matter of any one of Examples 18-21 can optionally include that the instructions are further to cause the memory controller to send the first reference voltage value to the memory device when the memory device is not in the per-device addressability mode.

In Example 23, the subject matter of any one of Examples 18-22 can optionally include that the instructions are further to cause the memory controller to send the first reference voltage value to the memory device as part of a command, the command not being exclusive to the memory device, the command also intended to set the first reference voltage value in the other memory devices in circuit with the memory device.

In Example 24, the subject matter of any one of Examples 18-23 can optionally include that the instructions are further to cause the memory controller to send the second reference voltage value to the memory device as part of a command, the command being intended to be processed by the memory device exclusive of one or more of the other memory devices in circuit with the memory device.

In Example 25, the subject matter of any one of Examples 18-24 can optionally include that the instructions are to cause the memory controller to send the first and second reference voltage values to the memory device using corresponding mode register set commands.

Example 26 is a memory controller to configure reference voltage values for use with data lines of a memory device. The memory controller of Example 26 includes: a voltage controller to: select a first reference voltage value for use by the memory device to determine a first logic value at a data line of the memory device during a per-device addressability mode, the per-device addressability mode to enable access to the memory device exclusive of other memory devices in circuit with the memory device; and select a second reference voltage value for use by the memory device during operation of the memory device in a non-per-device addressability mode to determine a second logic value at the data line of the memory device during a write operation, the non-per-device addressability mode to enable writing data to the memory device; and a memory interface to send the first and second reference voltage values to the memory device for setting in the memory device.

In Example 27, the subject matter of Example 26 can optionally include a command generator to generate a first command to cause the memory device to store the first reference voltage value in a mode register of the memory device, and generate a second command to cause the memory device to store the second reference voltage value in the mode register.

In Example 28, the subject matter of any one of Examples 26-27 can optionally include that the first command is to cause the memory device to set the first reference voltage value using a first field of the mode register during the non-per-device addressability mode, and the second command is to cause the memory device to set the second reference voltage value using a second field of the mode register during the per-device addressability mode.

In Example 29, the subject matter of any one of Examples 26-28 can optionally include a comparator to determine when a reference voltage margin of the memory device is not reached based on a comparison of a first binary value written to the memory device and a second binary value read from the memory device, and the voltage controller is further to select a third reference voltage value to overwrite the second reference voltage value using the second field of the mode register without overwriting the first reference voltage value in the first field of the mode register.

In Example 30, the subject matter of any one of Examples 26-29 can optionally include that the memory interface is to send the first reference voltage value to the memory device when the memory device is not in the per-device addressability mode.

In Example 31, the subject matter of any one of Examples 26-30 can optionally include a command generator to generate a command to send the first reference voltage value to the memory device, the command not being exclusive to the memory device, the command also intended to set the first reference voltage value in the other memory devices in circuit with the memory device.

In Example 32, the subject matter of any one of Examples 26-31 can optionally include a command generator to generate a command to send the second reference voltage value to the memory device, the command being intended to be processed by the memory device exclusive of one or more of the other memory devices in circuit with the memory device.

Example 33 an apparatus including the memory controller of any one of claims Examples 26-32, and further including: one or more processors; a network interface in communication with the one or more processors; and a memory device in communication with the one or more processors and the memory controller, the memory device to receive the first reference voltage value and the second reference voltage value from the memory interface of the memory controller.

Example 34 is a memory controller to configure reference voltage values for use with data lines of a memory device. The memory controller of Example 34 includes: voltage selection means for: selecting a first reference voltage value for use by the memory device to determine a first logic value at a data line of the memory device during a per-device addressability mode, the per-device addressability mode to enable access to the memory device exclusive of other memory devices in circuit with the memory device; and selecting a second reference voltage value for use by the memory device during operation of the memory device in a non-per-device addressability mode to determine a second logic value at the data line of the memory device during a write operation, the non-per-device addressability mode to enable writing data to the memory device; and memory interface means for sending the first and second reference voltage values to the memory device for setting in the memory device.

In Example 35, the subject matter of Example 34 can optionally include command generation means for generating a first command to cause the memory device to store the first reference voltage value in a mode register of the memory device, and generating a second command to cause the memory device to store the second reference voltage value in the mode register.

In Example 36, the subject matter of any one of Examples 34-35 can optionally include that the first command is to cause the memory device to set the first reference voltage value using a first field of the mode register during the non-per-device addressability mode, and the second command is to cause the memory device to set the second reference voltage value using a second field of the mode register during the per-device addressability mode.

In Example 37, the subject matter of any one of Examples 34-36 can optionally include comparator means for determining when a reference voltage margin of the memory device is not reached based on a comparison of a first binary value written to the memory device and a second binary value read from the memory device, and the voltage selection means further for selecting a third reference voltage value to overwrite the second reference voltage value using the second field of the mode register without overwriting the first reference voltage value in the first field of the mode register.

In Example 38, the subject matter of any one of Examples 34-37 can optionally include that the memory interface means is for sending the first reference voltage value to the memory device when the memory device is not in the per-device addressability mode.

In Example 39, the subject matter of any one of Examples 34-38 can optionally include a command generation means for generating a command to send the first reference voltage value to the memory device, the command not being exclusive to the memory device, the command also intended to set the first reference voltage value in the other memory devices in circuit with the memory device.

In Example 40, the subject matter of any one of Examples 34-39 can optionally include a command generation means for generating a command to send the second reference voltage value to the memory device, the command being intended to be processed by the memory device exclusive of one or more of the other memory devices in circuit with the memory device.

Example 41 is an apparatus including the memory controller of any one of Examples 34-40, and further including: one or more processors; a network interface in communication with the one or more processors; and a memory device in communication with the one or more processors and the memory controller, the memory device to receive the first reference voltage value and the second reference voltage value from the memory interface means of the memory controller.

Example 42 is a memory device to configure reference voltage values for use with data lines of the memory device. The memory device of Example 42 includes: mode register interface means for: setting a first reference voltage value in the memory device for use during operation of the memory device in a per-device addressability mode, the first reference voltage value for use by the memory device to determine a first logic value at a data line of the memory device during the per-device addressability mode, the per-device addressability mode to enable access to the memory device exclusive of other memory devices in circuit with the memory device; and setting a second reference voltage value in the memory device for use during operation of the memory device in a non-per-device addressability mode, the non-per-device addressability mode to enable writing data to the memory device, the second reference voltage value for use by the memory device to determine a second logic value at the data line of the memory device during a write operation.

In Example 43, the subject matter of Example 42 can optionally include mode register means, the mode register interface means for setting the first and second reference voltage values in the mode register means.

In Example 44, the subject matter of any one of Examples 42-43 can optionally include a first field and a second field of the mode register means, the mode register interface means for setting the first reference voltage value using the first field of the mode register means during the non-per-device addressability mode, and the mode register interface means for setting the second reference voltage value using the second field of the mode register means during the per-device addressability mode.

In Example 45, the subject matter of any one of Examples 42-44 can optionally include that the mode register interface means is further for, when a reference voltage margin of the memory device is not reached based on the second reference voltage value, overwriting the second reference voltage value using the second field of the mode register means without overwriting the first reference voltage value in the first field of the mode register means.

In Example 46, the subject matter of any one of Examples 42-45 can optionally include data receiver means for receiving the first reference voltage value at the memory device when the memory device is not in the per-device addressability mode.

In Example 47, the subject matter of any one of Examples 42-46 can optionally include command decoder means for receiving the first reference voltage value at the memory device as part of a command from a memory controller, the command not being exclusive to the memory device, the command also intended to set the first reference voltage value in the other memory devices in circuit with the memory device.

In Example 48, the subject matter of any one of Examples 42-47 can optionally include command decoder means for receiving the second reference voltage value at the memory device as part of a command from a memory controller, the command being intended to be processed by the memory device exclusive of one or more of the other memory devices in circuit with the memory device.

Example 49 is an apparatus including the memory device of any one of Examples 42-48, and further including: one or more processors; a network interface in communication with the one or more processors; and a memory controller in communication with the one or more processors and the memory device, the memory controller to send the first reference voltage value and the second reference voltage value to the memory device.

Although certain example methods, apparatus and articles of manufacture have been disclosed herein, the scope of coverage of this patent is not limited thereto. On the contrary, this patent covers all methods, apparatus and articles of manufacture fairly falling within the scope of the claims of this patent.

1. A method to configure reference voltage values for use with data lines of a memory device, the method comprising:
setting a first reference voltage value in the memory device for use during operation of the memory device in a per-device addressability mode, the first reference voltage value for use by the memory device to determine a first logic value at a data line of the memory device during the per-device addressability mode, the per-device addressability mode to enable access to the memory device exclusive of other memory devices in circuit with the memory device; and
setting a second reference voltage value in the memory device for use during operation of the memory device in a non-per-device addressability mode, the non-per-device addressability mode to enable writing data to the memory device, the second reference voltage value for use by the memory device to determine a second logic value at the data line of the memory device during a write operation.

2. A method as defined in claim 1, wherein the setting of the first and second reference voltage values in the memory device includes storing the first and second reference voltage values in a mode register of the memory device.

3. A method as defined in claim 2, further including setting the first reference voltage value using a first field of the mode register during the non-per-device addressability mode, and setting the second reference voltage value using a second field of the mode register during the per-device addressability mode.

4. A method as defined in claim 3, further including, when a reference voltage margin of the memory device is not reached based on the second reference voltage value, overwriting the second reference voltage value in the second field of the mode register without overwriting the first reference voltage value in the first field of the mode register.

5. A method as defined in claim 1, further including receiving the first reference voltage value at the memory device when the memory device is not in the per-device addressability mode.

6. A method as defined in claim 1, further including receiving the first reference voltage value at the memory device as part of a command from a memory controller, the command not being exclusive to the memory device, the command also intended to set the first reference voltage value in the other memory devices in circuit with the memory device.

7. A method as defined in claim 1, further including receiving the second reference voltage value at the memory device as part of a command from a memory controller, the command being intended to be processed by the memory device exclusive of one or more of the other memory devices in circuit with the memory device.

8. A method as defined in claim 1, wherein the setting of the first and second reference voltage values in the memory device is performed by a memory controller sending corresponding mode register set commands to the memory device.

9. A method as defined in claim 1, wherein the setting of the first and second reference voltage values in the memory device is performed by the memory device based on receiving corresponding mode register set commands from a memory controller.

10. A memory device to configure reference voltage values for use with data lines of the memory device, the memory device comprising:
a mode register interface to:
set a first reference voltage value in the memory device for use during operation of the memory device in a per-device addressability mode, the first reference voltage value for use by the memory device to determine a first logic value at a data line of the memory device during the per-device addressability mode, the per-device addressability mode to enable access to the memory device exclusive of other memory devices in circuit with the memory device; and
set a second reference voltage value in the memory device for use during operation of the memory device in a non-per-device addressability mode, the non-per-device addressability mode to enable writing data to the memory device, the second reference voltage value for use by the memory device to determine a second logic value at the data line of the memory device during a write operation.

11. A memory device as defined in claim 10, further including a mode register, the mode register interface to set the first and second reference voltage values in the mode register.

12. A memory device as defined in claim 11, further including a first field and a second field of the mode register, the mode register interface to set the first reference voltage value using the first field of the mode register during the non-per-device addressability mode, and the mode register interface to set the second reference voltage value using the second field of the mode register during the per-device addressability mode.

13. A memory device as defined in claim 12, wherein the mode register interface is further to, when a reference voltage margin of the memory device is not reached based on the second reference voltage value, overwrite the second reference voltage value using the second field of the mode register without overwriting the first reference voltage value in the first field of the mode register.

14. A memory device as defined in claim 10, further including a data receiver to receive the first reference voltage value at the memory device when the memory device is not in the per-device addressability mode.

15. A memory device as defined in claim 10, further including a command decoder to receive the first reference voltage value at the memory device as part of a command from a memory controller, the command not being exclusive to the memory device, the command also intended to set the first reference voltage value in the other memory devices in circuit with the memory device.

16. A memory device as defined in claim 10, further including a command decoder to receive the second reference voltage value at the memory device as part of a command from a memory controller, the command being intended to be processed by the memory device exclusive of one or more of the other memory devices in circuit with the memory device.

17. An apparatus including the memory device of claim 10, and further including:
one or more processors;
a network interface in communication with the one or more processors; and
a memory controller in communication with the one or more processors and the memory device, the memory controller to send the first reference voltage value and the second reference voltage value to the memory device.

18. At least one article of manufacture comprising machine readable instructions that, when executed, cause a memory controller to at least:
set a first reference voltage value in a memory device for use during operation of the memory device in a per-device addressability mode, the first reference voltage value for use by the memory device to determine a first logic value at a data line of the memory device during the per-device addressability mode, the per-device addressability mode to enable access to the memory device exclusive of other memory devices in circuit with the memory device; and
set a second reference voltage value in the memory device for use during operation of the memory device in a non-per-device addressability mode, the non-per-device addressability mode to enable writing data to the memory device, the second reference voltage value for use by the memory device to determine a second logic value at the data line of the memory device during a write operation.

19. At least one article of manufacture of claim 18, wherein the setting of the first and second reference voltage values in the memory device includes sending the first and second reference voltage values to the memory device to store in a mode register of the memory device.

20. At least one article of manufacture of claim 19, wherein the instructions are to cause the memory controller to set the first and second reference voltage values in the memory device by sending the first reference voltage value to the memory device during the non-per-device addressability mode to store using a first field of the mode register, and sending the second reference voltage value to the memory device during the per-device addressability mode to store using a second field of the mode register.

21. At least one article of manufacture of claim 20, wherein the instructions are further to cause the memory controller to, when a reference voltage margin of the memory device is not reached based on the second reference voltage value, overwrite the second reference voltage value using the second field of the mode register without overwriting the first reference voltage value in the first field of the mode register.

22. At least one article of manufacture of claim 18, wherein the instructions are further to cause the memory controller to send the first reference voltage value to the memory device when the memory device is not in the per-device addressability mode.

23. At least one article of manufacture of claim 18, wherein the instructions are further to cause the memory controller to send the first reference voltage value to the memory device as part of a command, the command not being exclusive to the memory device, the command also intended to set the first reference voltage value in the other memory devices in circuit with the memory device.

24. At least one article of manufacture of claim 18, wherein the instructions are further to cause the memory controller to send the second reference voltage value to the memory device as part of a command, the command being intended to be processed by the memory device exclusive of one or more of the other memory devices in circuit with the memory device.

25. At least one article of manufacture of claim 18, wherein the instructions are to cause the memory controller to send the first and second reference voltage values to the memory device using corresponding mode register set commands.

26-49. (canceled)
